(19) United States
(12) Patent Application Publication
(10) Pub. No.: US 2024/0315006 A1
(43) Pub. Date: Sep. 19, 2024

(54) SEMICONDUCTOR DEVICES

(71) Applicant: Samsung Electronics Co., Ltd., Suwon-si (KR)

(72) Inventors: Kiseok Lee, Suwon-si (KR); Huijung Kim, Suwon-si (KR); Sangjae Park, Suwon-si (KR); Taejin Park, Suwon-si (KR); Junhyeok Ahn, Suwon-si (KR); Chansic Yoon, Suwon-si (KR); Myeongdong Lee, Seoul (KR)

(21) Appl. No.: 18/424,447

(22) Filed: Jan. 26, 2024

(30) Foreign Application Priority Data
Mar. 14, 2023 (KR) 10-2023-0033111

(51) Int. Cl. H10B 12/00

(52) U.S. Cl. CPC H10B 12/315; H10B 12/0335; H10B 12/482

(57) ABSTRACT

A semiconductor device includes an active pattern array including active patterns on a substrate, a first contact structure on a central portion of each active pattern, a bit line structure on the first contact structure, a second contact structure on an end portion of each active pattern, a third contact structure on the second contact structure, a filling pattern between the bit line structure and the third contact structure and including a void, and a capacitor electrically connected to the third contact structure. The active pattern array includes active pattern rows spaced apart from each other in a first direction, and each active pattern row includes the active patterns spaced apart from each other in a second direction. Each active pattern extends in a third direction, and the active patterns in each active pattern row are aligned in the second direction.

### CROSS-REFERENCE TO RELATED APPLICATION

This application claims priority under 35 U.S.C. § 119 to Korean Patent Application No. 10-2023-0033111 filed on Mar. 14, 2023 in the Korean Intellectual Property Office, the disclosure of which is hereby incorporated by reference in its entirety.

### TECHNICAL FIELD

Example embodiments of the present disclosure relate to a semiconductor device. More particularly, example embodiments of the present disclosure relate to a DRAM device.

### DISCUSSION OF RELATED ART

A DRAM device includes: gate structures which extend through upper portions of active patterns in a first direction; bit line structures on central portions of the active patterns, each of which extends in a second direction; contact plug structures on opposite end portions, respectively, of corresponding ones of the active patterns; and capacitors on corresponding ones, respectively, of the contact plug structures.

As the DRAM device has been highly integrated, a distance between the bit line structure and the contact plug structure decreases, so that an electrical short may occur therebetween.

### SUMMARY

Example embodiments provide a semiconductor device having improved electrical characteristics.

According to example embodiments, a semiconductor device includes an active pattern array including active patterns on a substrate; a first contact on a central portion of each of the active patterns; a bit line on the first contact; a second contact on an end portion of each of the active patterns; a third contact on the second contact; a filling pattern between the bit line and the third contact, the filling pattern including a void therein; and a capacitor electrically connected to the third contact, wherein the active pattern array includes active pattern rows spaced apart from each other in a first direction parallel to an upper surface of the substrate, each of the active pattern rows includes a plurality of active patterns spaced apart from each other in a second direction parallel to the upper surface of the substrate and orthogonal to the first direction, each of the active patterns extends in a third direction forming an acute angle with the first direction and the second direction, and the plurality of active patterns in each row of the active pattern rows are aligned with each other in the second direction.

According to example embodiments, a semiconductor device includes an active pattern on a substrate; a first contact on a central portion of the active pattern; a bit line on the first contact; a second contact on an end portion of the active pattern; a third contact on the second contact; a filling pattern between the bit line and the third contact, the filling pattern including a void therein; a barrier pattern on the second contact, the barrier pattern covering a lower surface of the third contact and a lower surface of the filling pattern; a fourth contact contacting an upper surface of the third contact and an upper surface of the filling pattern; and a capacitor electrically connected to the fourth contact.

According to example embodiments, a semiconductor device includes an active pattern array including active patterns on a substrate; an isolation pattern on the substrate, the isolation pattern covering sidewalls of the active patterns; gates spaced apart from each other in a first direction parallel to an upper surface of the substrate, each of the gates extending through the active patterns and an upper portion of the isolation pattern in a second direction parallel to the upper surface of the substrate and orthogonal to the first direction; a first contact on a central portion of each of the active patterns; bit lines spaced apart from each other in the second direction, each of the bit lines extending in the first direction on central portions of the active patterns and the isolation pattern; a second contact on an end portion of each of the active patterns; a barrier pattern on the second contact; a third contact on the barrier pattern; a filling pattern between the bit line and the third contact, the filling pattern including a void therein; a fourth contact on the third contact and the filling pattern; a landing pad on the fourth contact; and a capacitor on the landing pad, wherein the active pattern array includes active pattern rows spaced apart from each other in the second first direction, each of the active pattern rows includes a plurality of active patterns spaced apart from each other in the second direction, each of the active patterns extends in a third direction forming an acute angle with the first direction and the second direction, and the plurality of active patterns in each row of the active pattern rows are aligned with each other in the second direction.

In the semiconductor device in accordance with example embodiments, the filling pattern including an insulating material may be disposed between the contact structure on the end portion of the active pattern and the bit line structure overlapping the central portion of the active pattern, and thus the electrical short may be prevented or reduced. Additionally, the filling pattern may include a void therein, and thus the parasitic capacitance between the bit line structure and the contact structure may be reduced.

### BRIEF DESCRIPTION OF THE DRAWINGS

FIGS. 1 to 3 are a plan view and cross-sectional views illustrating a semiconductor device in accordance with example embodiments.

FIGS. 4 to 39 are plan views and cross-sectional views illustrating a method of manufacturing a semiconductor device in accordance with example embodiments.

FIG. 40 is a cross-sectional view illustrating a semiconductor device in accordance with example embodiments.

FIGS. 41 to 45 are a plan view and cross-sectional views illustrating a semiconductor device in accordance with example embodiments.

### DETAILED DESCRIPTION

The above and other aspects and features of the capacitor structures and the methods of manufacturing the same, the semiconductor devices including the capacitor structures and the methods of manufacturing the same in accordance with example embodiments will become readily understood from detail descriptions that follow, with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively.

Terms such as “same,” “equal,” “planar,” “coplanar,” “parallel,” “perpendicular”, and “orthogonal” as used herein encompass identicality or near identicality including variations that may occur, for example, due to manufacturing processes. The term “substantially” may be used herein to emphasize this meaning, unless the context or other statements indicate otherwise.

Hereinafter, two directions among horizontal directions that are substantially parallel to an upper surface of a substrate, which may be substantially orthogonal to each other, may be referred as first and second directions D1 and D2, respectively, and two other directions among the horizontal directions, which may have an acute angle with respect to each of the first and second directions D1 and D2 and substantially orthogonal to each other, may be referred to as third and fourth directions D3 and D4, respectively.

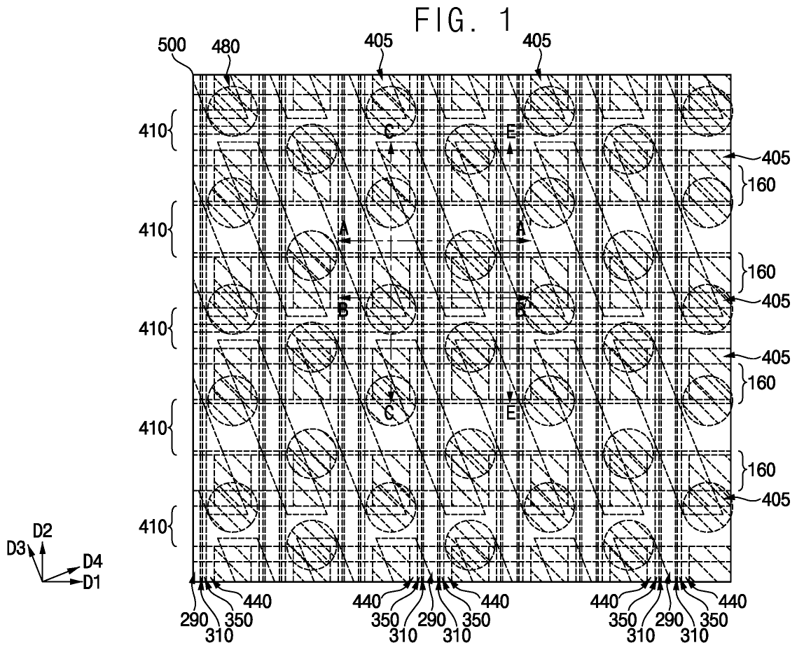

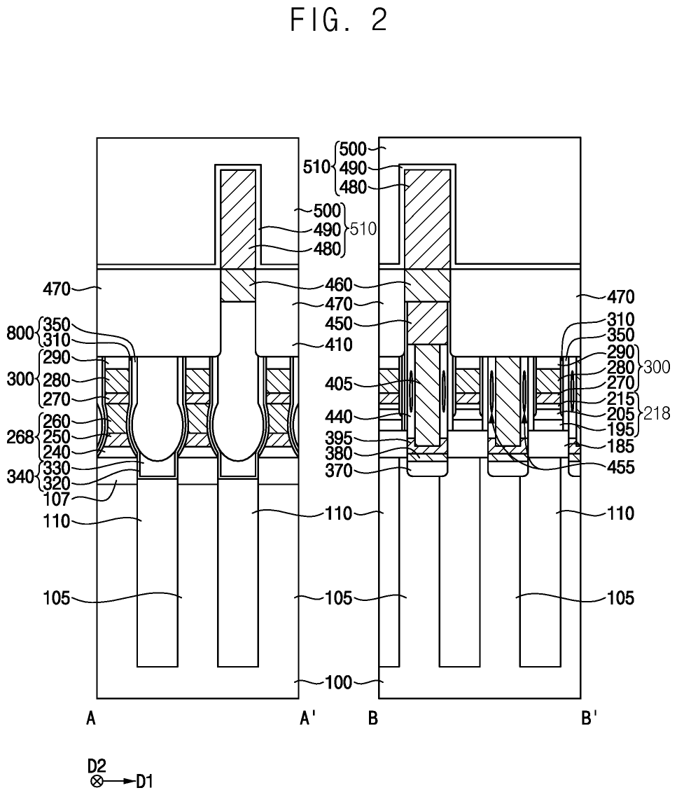

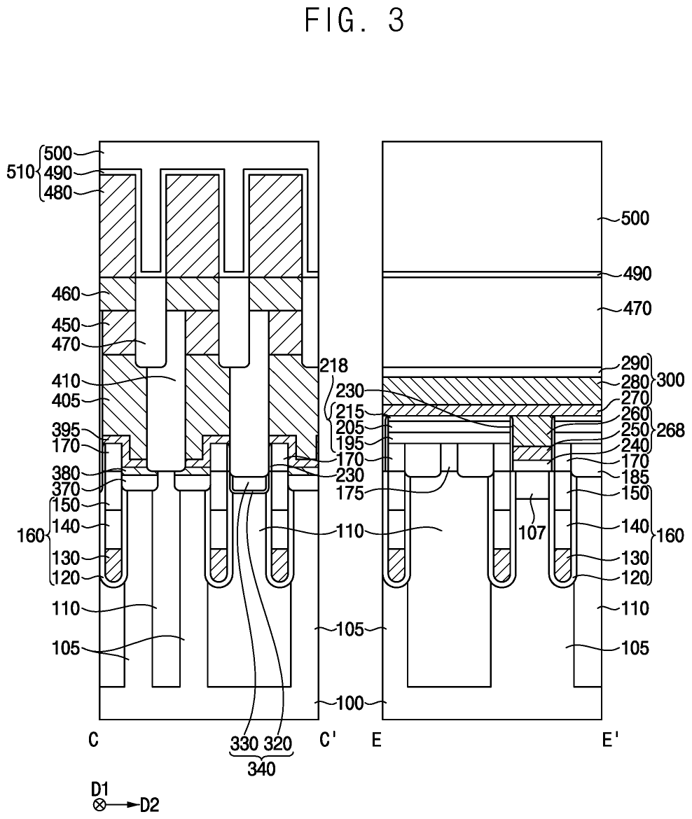

FIGS. 1 to 3 are a plan view and cross-sectional views illustrating a semiconductor device in accordance with example embodiments. Specifically, FIG. 1 is the plan view, FIG. 2 includes cross-sectional views taken along lines A-A′ and line B-B′, respectively, of FIG. 1, and FIG. 3 includes cross-sectional views taken along lines C-C′ and line E-E′, respectively, of FIG. 1.

The semiconductor device may include an active pattern 105, a gate structure 160 (e.g., a gate), a bit line structure 300 (e.g, a bit line), a filling structure 340 (e.g., a filling), a buffer structure 218 (e.g., a buffer), a fence pattern 410, a first contact structure 268 (e.g., a first contact), a second contact structure 370 (e.g., a second contact), a third contact structure 405 (e.g., a third contact), a second barrier pattern 395, a fourth contact structure 450 (e.g., a fourth contact), a spacer structure 800 (e.g., a spacer), a third filling pattern 440, a landing pad 460 and a capacitor 510 on a substrate 100.

The semiconductor device may further include an isolation pattern 110, a first mold layer 170, a second mold layer 175, a third mold 185, a first spacer 230, a second ohmic contact pattern 380 and an insulation pattern 470.

The substrate 100 may be formed of or include silicon, germanium, silicon-germanium, or a III-V group compound semiconductor, e.g., GaP, GaAs, GaSb, etc. In example embodiments, the substrate 100 may be a silicon-on-insulator (SOI) substrate or a germanium-on-insulator (GOI) substrate.

The active pattern 105 may be defined on the substrate 100, and a sidewall of the active pattern 105 may be covered by the isolation pattern 110 on the substrate 100.

An item, layer, or portion of an item or layer described as “extending” in a particular direction has a length in the particular direction and a width perpendicular to that direction, where the length is greater than the width.

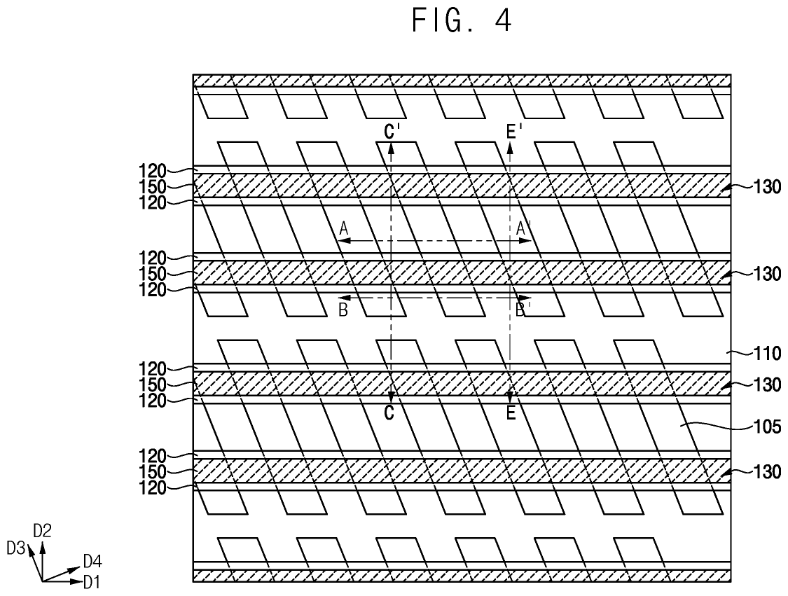

The active pattern 105 may extend in the third direction D3 to a certain length (see, e.g., FIG. 4), and a plurality of active patterns 105 may be spaced apart from each other in the first direction D1 to form an active pattern row. Additionally, a plurality of active pattern rows may be spaced apart from each other in the second direction D2 to form an active pattern array. In example embodiments, the active patterns 105 in each of the active pattern rows may be aligned with each other in the first direction D1. That is, end portions of a plurality of active patterns 105 disposed in the first direction D1, which may be in the same active pattern row, may be aligned with each other along the first direction D1. For example, the active pattern array may be formed of rows and columns of active patterns 105. End portions of active patterns 105 in the same row may be aligned in the first direction D1 and end portions of active patterns 105 in the same column may be aligned in the second direction D2 as shown, e.g., in FIG. 1.

The active pattern 105 may be formed of or include a material substantially the same as a material of the substrate 100, and the isolation pattern 110 may include an oxide, e.g., silicon oxide. A first impurity region 107 may be disposed at an upper portion of a central portion of the active pattern 105 in the third direction D3. In example embodiments, a second impurity region may be disposed at an upper portion of each of end portions of the active pattern 105 in the third direction D3. Each of the first impurity region 107 and the second impurity region may include, for example, n-type impurities or p-type impurities.

The gate structure 160 may extend in the first direction D1 through upper portions of the active pattern 105 and the isolation pattern 110, and a plurality of gate structures 160 may be spaced apart from each other in the second direction D2. The gate structure 160 may include a first conductive pattern 130, a second conductive pattern 140 and a first mask 150 sequentially stacked in a vertical direction substantially perpendicular to an upper surface of the substrate 100, and further include a gate insulation pattern 120, which may cover sidewalls of the first conductive pattern 130, the second conductive pattern 140 and the first mask 150 and a lower surface of the first conductive pattern 130.

The gate insulation pattern 120 may be formed of or include an oxide, e.g., silicon oxide, the first conductive pattern 130 may be formed of or include, e.g., a metal, a metal nitride, a metal silicide, etc., the second conductive pattern 140 may be formed of or include, e.g., polysilicon doped with n-type impurities or p-type impurities, and the first mask 150 may be formed of or include an insulating nitride, e.g., silicon nitride. In an embodiment, two gate structures 160 spaced apart from each other in the second direction D2 may extend through an upper portion of a single active pattern 105.

In another embodiment, a dummy gate structure extending in the first direction D1 through an upper portion of the isolation pattern 110 between the active pattern rows and an upper portion of each of the active patterns 105 adjacent to the upper portion of the isolation pattern 110 may be further disposed.

The first contact structure 268 may be disposed on the central portion of the active pattern 105, and may include a pad 240, a first ohmic contact pattern 250 and a second metal pattern 260 sequentially stacked in the vertical direction. In example embodiments, a plurality of first contact structures 268 may be spaced apart from each other in the first and second directions D1 and D2. The pad 240 may be formed of or include, e.g., polysilicon doped with impurities, the first ohmic contact pattern 250 may be formed of or include a metal silicide, e.g., cobalt silicide, nickel silicide, titanium silicide, etc., and the second metal pattern 260 may be formed of or include a metal, e.g., tungsten, niobium, copper, aluminum, etc.

The first mold layer 170, the second mold layer 175 and the third mold 185 may be disposed on the active pattern 105 and the isolation pattern 110. The first mold layer 170 may extend in the first direction D1, and a plurality of first mold layers 170 may be spaced apart from each other in the second direction D2. A plurality of second mold layers 175 may be spaced apart from each other in the first and second directions D1 and D2, and a plurality of third molds 185 may be spaced apart from each other in the first and second directions D1 and D2. The second mold layers 175 and the third molds 185 may be disposed under the bit line structure 300.

In example embodiments, upper surfaces of the first and second mold layers 170 and 175 and an upper surface of the third mold 185 may be substantially coplanar with each other. Also, the third mold 185 may have a lower surface lower than lower surfaces of the first and second mold layers 170 and 175.

The first mold layer 170 and the second mold layer 175 may be formed of or include an insulating nitride, e.g., silicon nitride, and the third mold 185 may be formed of or include an oxide, e.g., silicon oxide.

The buffer structure 218 may be disposed between the third mold 185 and the bit line structure 300, and may include first to third buffers 195, 205 and 215 sequentially stacked in the vertical direction. A plurality of buffer structures 218 may be spaced apart from each other in the first and second directions D1 and D2. The first buffer 195 may be formed of or include an oxide, e.g., silicon oxide, the second buffer 205 may be formed of or include a high-k material, and the third buffer 215 may be formed of or include a nitride, e.g., silicon nitride.

When an element is referred to as “contacting” or “in contact with” another element (or using any form of the word “contact”), there are no intervening elements present at the point of contact.

The bit line structure 300 may extend in the second direction D2, and a plurality of bit line structures 300 may be spaced apart from each other in the first direction D1. The bit line structure 300 may overlap the central portion of the active pattern 105 in the vertical direction, and the first contact structure 268 may be disposed between the bit line structure 300 and the active pattern 105. The bit line structure 300 may contact an upper surface of the buffer structure 218.

The bit line structure 300 may include a first barrier pattern 270, a third metal pattern 280 and a second mask 290 sequentially stacked in the vertical direction. The first barrier pattern 270 may be formed of or include a metal nitride, e.g., titanium nitride or a metal silicon nitride, e.g., titanium silicon nitride, the third metal pattern 280 may be formed of or include a metal, e.g., tungsten, and the second mask 290 may be formed of or include an insulating nitride, e.g., silicon nitride.

The filling structure 340 may be disposed on the isolation pattern 110 between the first contact structures 268 neighboring in the first direction D1. The filling structure 340 may have a lower surface lower than a lower surface of the first contact structure 268 or a lower surface of the third mold 185.

The filling structure 340 may include a second filling pattern 330 and a first filling pattern 320 covering a sidewall and a lower surface of the second filling pattern 330. The first filling pattern 320 may be formed of or include an oxide, e.g., silicon oxide or silicon oxycarbide, and the second filling pattern 330 may be formed of or include an insulating nitride, e.g., silicon nitride or silicon oxycarbonitride.

The first spacer 230 may be disposed on a sidewall of the first mold layer 170 and a sidewall of the buffer structure 218, and may contact a sidewall of the first contact structure 268. The first spacer 230 may be formed of or include an insulating nitride, e.g., silicon nitride.

The spacer structure 800 may include second and third spacers 310 and 350 stacked in the first direction D1 on a sidewall of the bit line structure 300 in the first direction, and may extend in the second direction D2. Each of the second and third spacers 310 and 350 may be formed of or include an insulating nitride, e.g., silicon nitride, and in some cases, the second and third spacers 310 and 350 may be merged with each other.

The second contact structure 370 may be disposed on each of opposite end portions of the active pattern 105, and may be formed of or include, e.g., polysilicon doped with impurities. The second ohmic contact pattern 380 may be disposed on the second contact structure 370, and may be formed of or include, e.g., metal silicide.

The second barrier pattern 395 may be disposed on the second ohmic contact pattern 380, the first mold layer 170 and the first spacer 230, and may contact a sidewall of the third mold 185 and a lower sidewall of the fence pattern 410. The second barrier pattern 395 may be formed of or include a metal nitride, e.g., titanium nitride, tantalum nitride, etc.

The third contact structure 405 may be disposed on the second barrier pattern 395. Each of opposite sidewalls in the first direction D1 of the third contact structure 405 may contact a sidewall of the third filling pattern 440, and each of opposite sidewalls in the second direction D2 of the third contact structure 405 may contact a sidewall of the fence pattern 410. In example embodiments, a lower surface of the third contact structure 405 and a lower portion of a sidewall in the first direction D1 of the third contact structure 405 may be covered by the second barrier pattern 395. In example embodiments, a lowermost surface of the third contact structure 405 may be lower than a lowermost surface of the second barrier pattern 395. The third contact structure 405 may be formed of or include a metal, e.g., tungsten, copper, aluminum, etc.

It should be appreciated that a “void” may include air or other gases (e.g., such as those present during manufacturing) or may include a gap forming a vacuum therein.

The third filling pattern 440 may contact an outer sidewall of the spacer structure on each of opposite sidewalls of the bit line structure 300 in the first direction D1 and a sidewall of the third contact structure 405. In example embodiments, a lower surface of the third filling pattern 440 may contact an upper surface of the second barrier pattern 395. In an example embodiment, a void 455 may be formed in the third filling pattern 440. The third filling pattern 440 may be formed of or include an oxide, e.g., silicon oxide.

The fence pattern 410 may overlap the central portion of the active pattern 105 in the vertical direction and may extend in the first direction D1, or may overlap, in the vertical direction, the end portions of the active patterns 105 facing each other in the third direction D3 and a portion of the isolation pattern 110 therebetween and may extend in the first direction D1. The fence pattern 410 may be disposed between the third contact structures 405 neighboring in the second direction D2. In an embodiment, the fence pattern 410 may extend in the first direction D1 through an upper portion of the bit line structure 300, and thus a lower surface of a portion of the fence pattern 410 in an area where the bit line structure 300 is formed may be higher than a lower surface of portions of the fence pattern 410 in other areas.

The fence pattern 410 may insulate other elements, layers, or components from each other and may be formed of or include an insulating nitride, e.g., silicon nitride, silicon oxycarbonitride, etc.

The fourth contact structure 450 may contact an upper surface of the third contact structure 405 and an upper surface of the third filling pattern 440, and may be formed of or include a metal, e.g., tungsten, copper, aluminum, etc.

The landing pad 460 may contact an upper surface of the fourth contact structure 450, and a plurality of landing pads 460 may be spaced apart from each other in the first and second directions D1 and D2. In example embodiments, the landing pad 460 may have a shape such as a circle, an ellipse, a polygon, a polygon with rounded corners, etc., in a plan view, and the landing pads 460 may be arranged in a honeycomb pattern. The landing pad 460 may be formed of or include a metal, a metal nitride, etc. The landing pads 460 may have dimensions in the first and second directions that are greater than any wire, pattern or line connected thereto. The upper surface of each of the landing pads 460 may be planar.

The insulation pattern 470 may cover sidewalls of the landing pads 460, and may partially extend through the upper portion of the bit line structure 300 and an upper portion of the fence pattern 410. The insulation pattern 470 may be formed of or include an insulating nitride, e.g., silicon nitride.

The capacitor 510 may include a first electrode 480, a dielectric layer 490 and a second electrode 500 sequentially stacked, and the first electrode 480 may contact an upper surface of the landing pad 460. Each of the first and second electrodes 480 and 500 may be formed of or include a metal, a metal nitride, a metal silicide, silicon-germanium doped with impurities, etc., and the dielectric layer 490 may include a metal oxide having a high dielectric constant.

In the semiconductor device, the bit line structure 300 may be electrically connected to the central portion of the active pattern 105 through the first contact structure 268, and the capacitor 510 may be electrically connected to the end portion of the active pattern 105 through the landing pad 460, the fourth contact structure 450, the second ohmic contact pattern 380 and the second contact structure 370.

The third filling pattern 440 may be disposed between the third contact structure 405 and the bit line structure 300, and thus an electrical short may be prevented therebetween. Additionally, the void 455 may be formed in the third filling pattern 440, and thus a parasitic capacitance between the bit line structure 300 and the third contact structure 405 may be reduced.

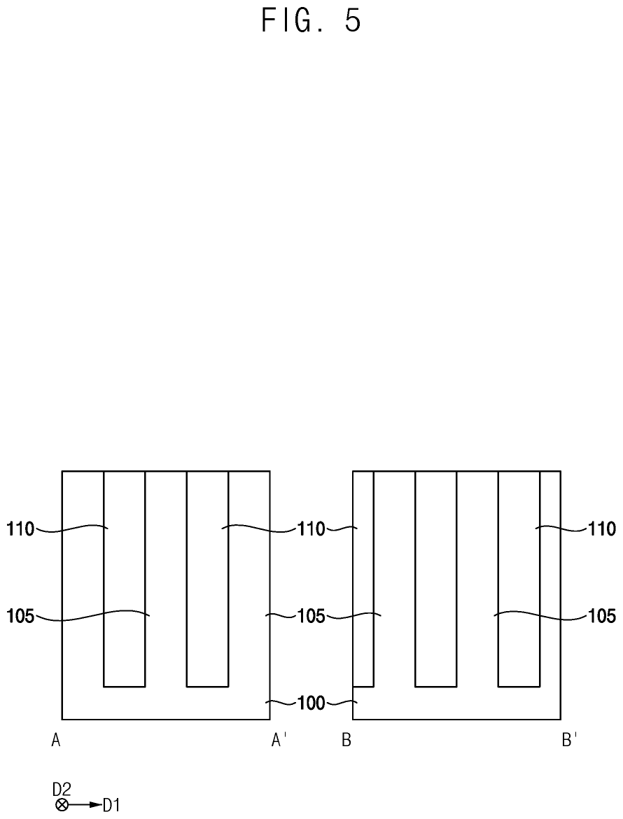

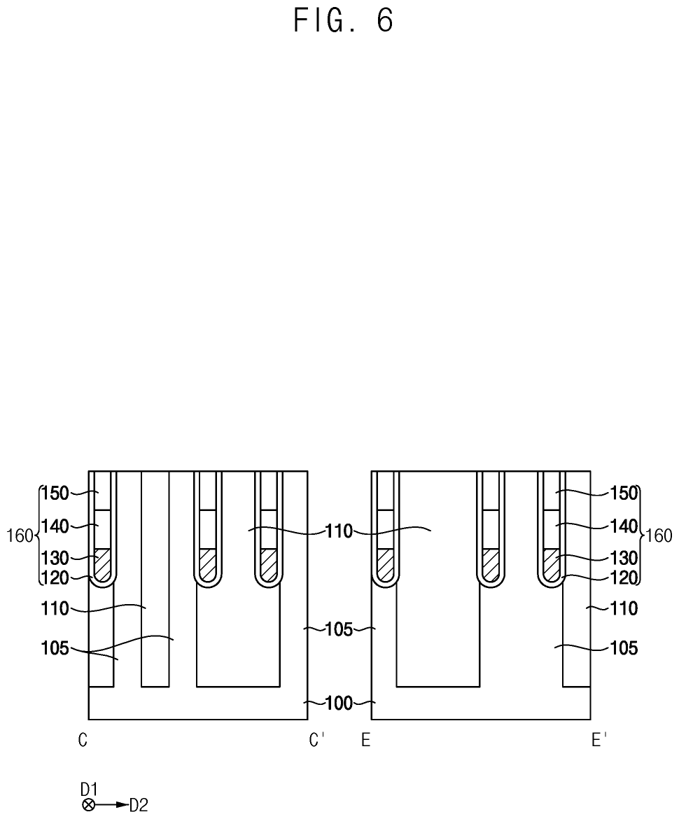

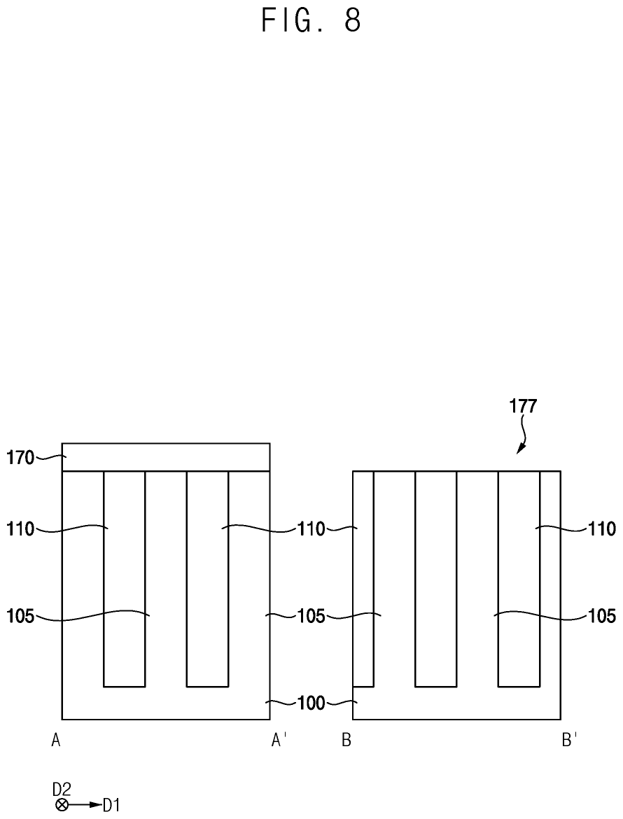

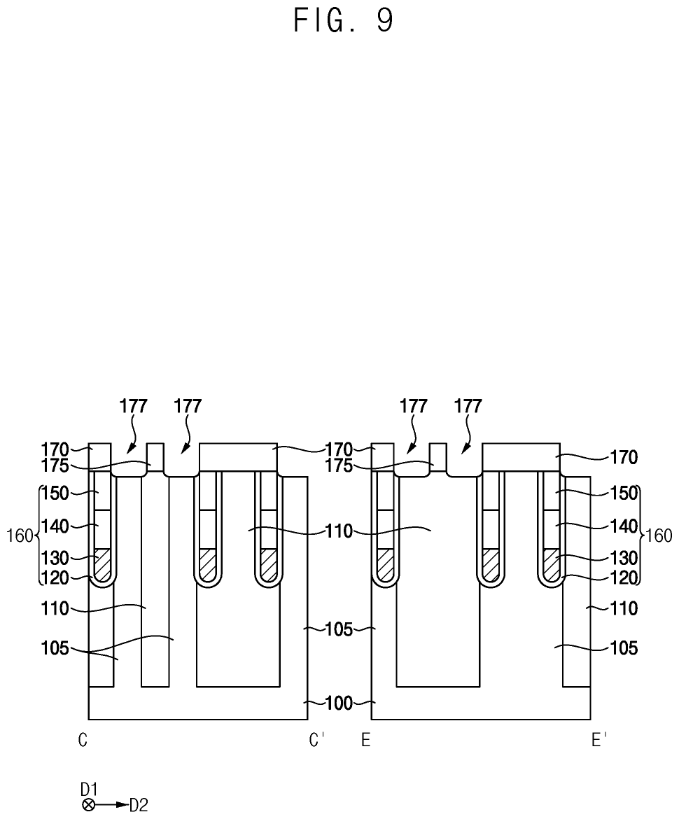

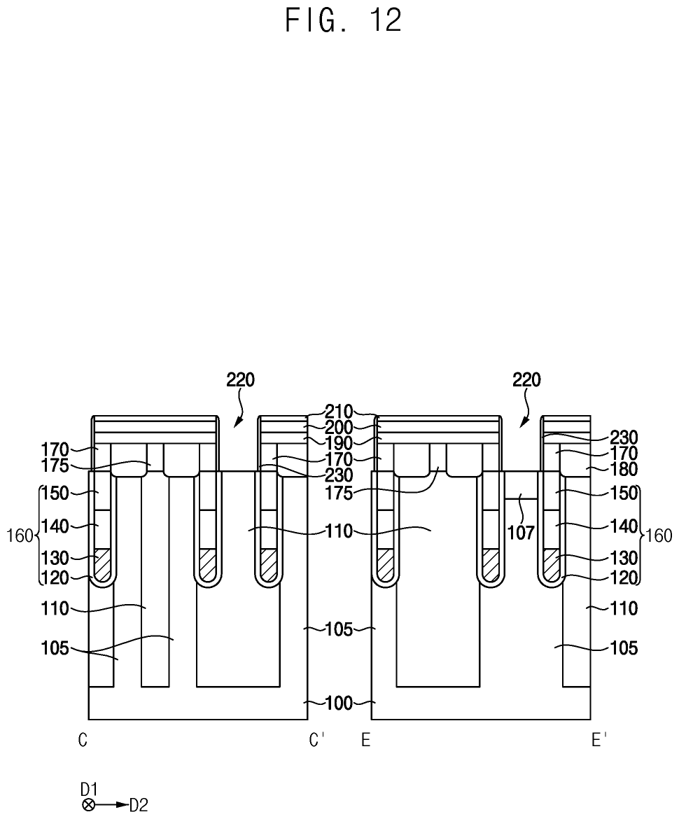

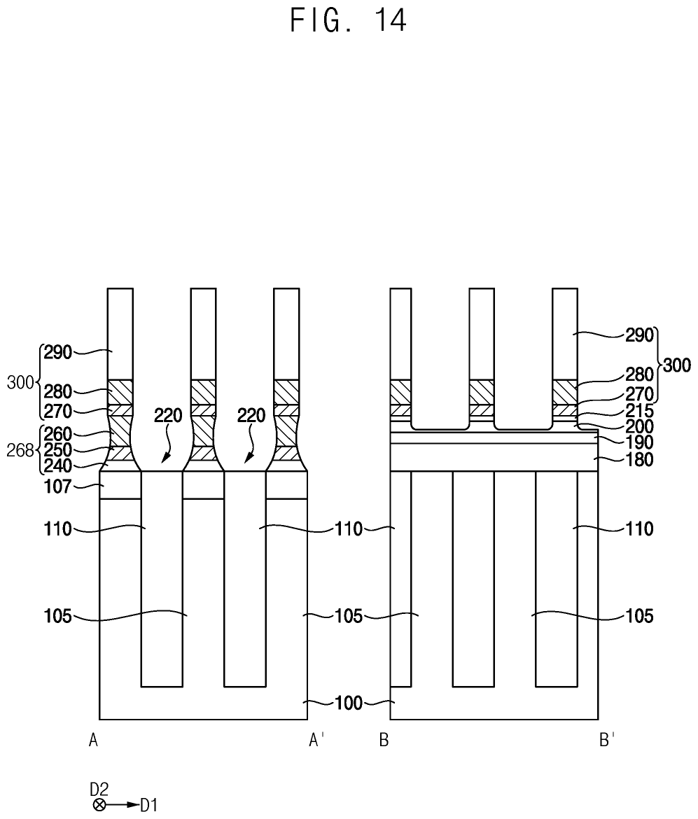

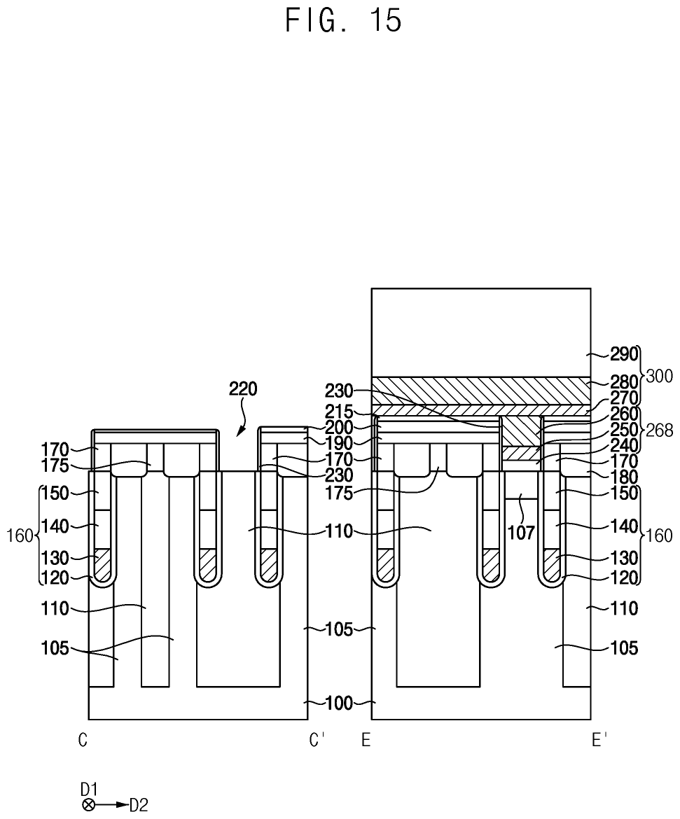

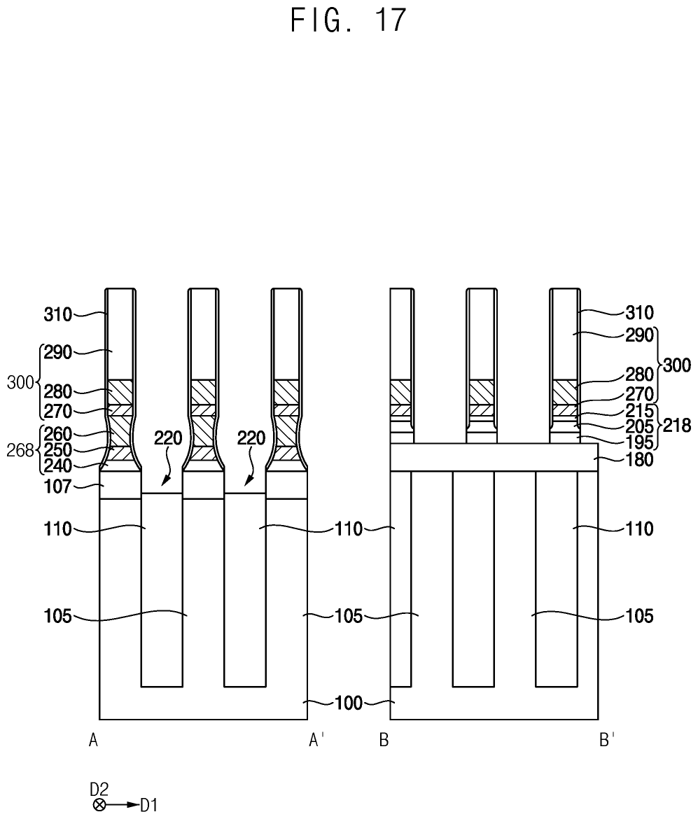

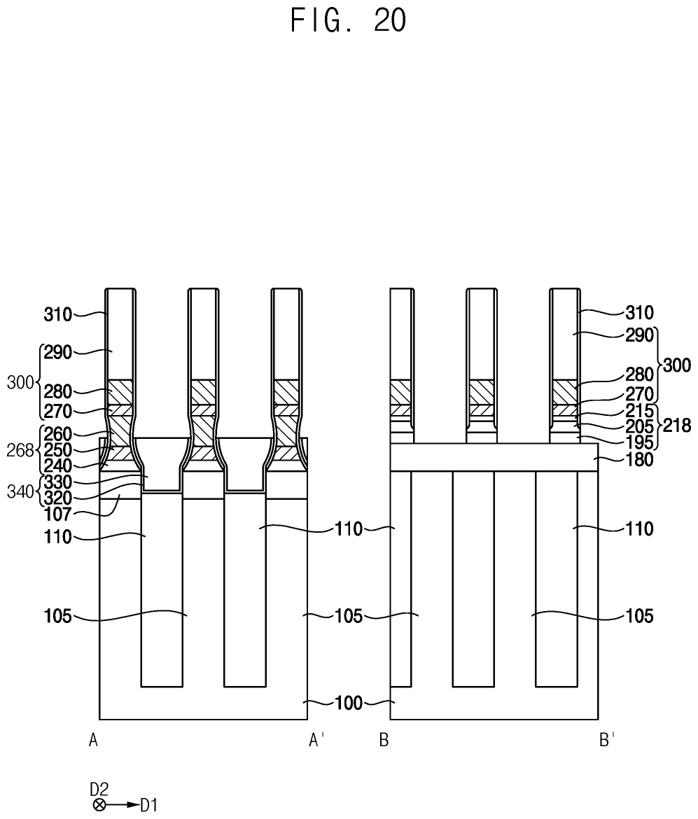

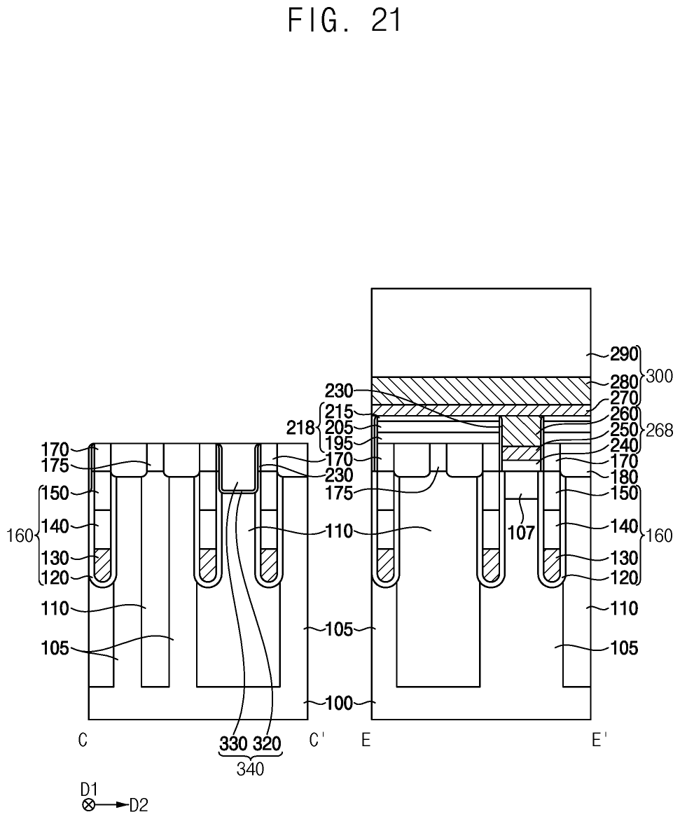

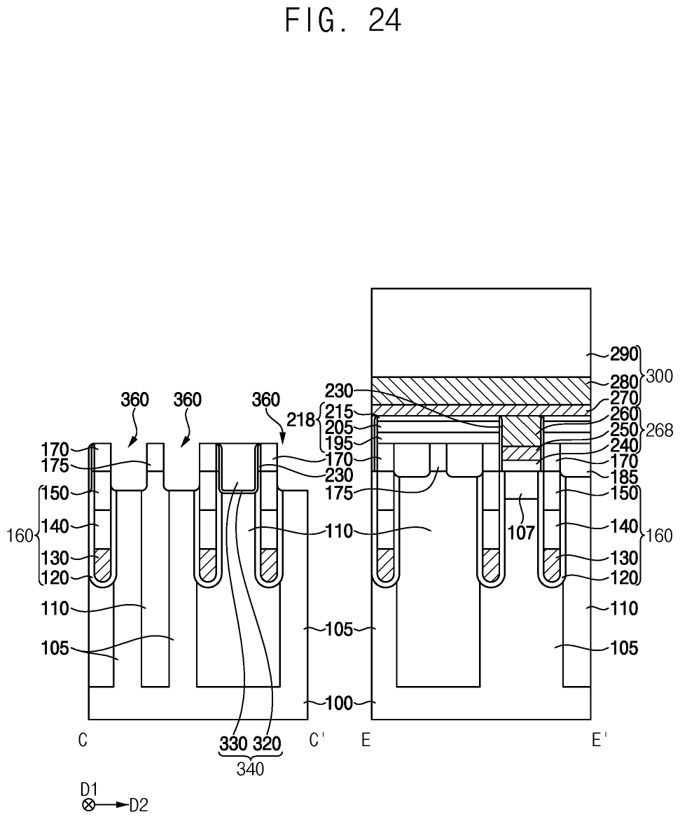

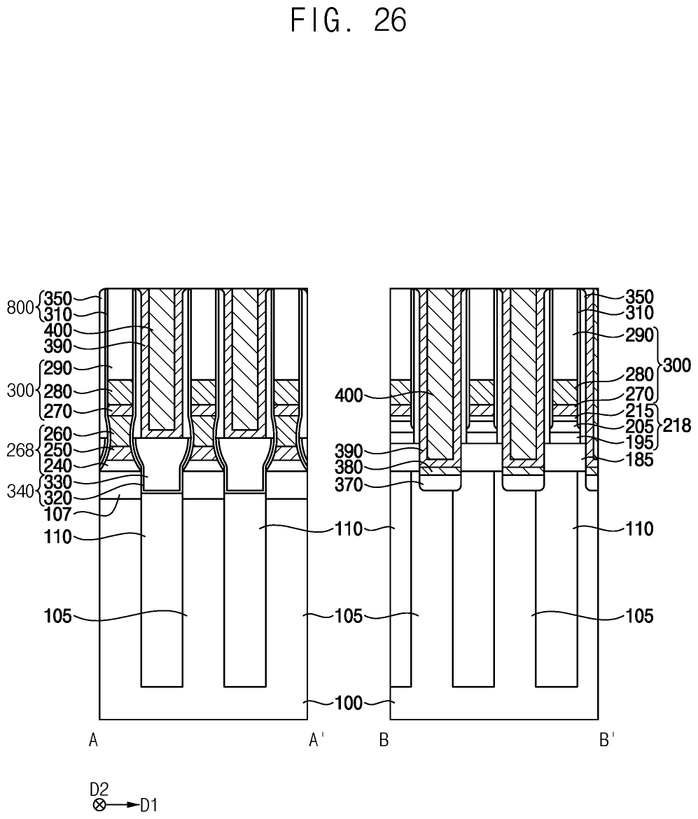

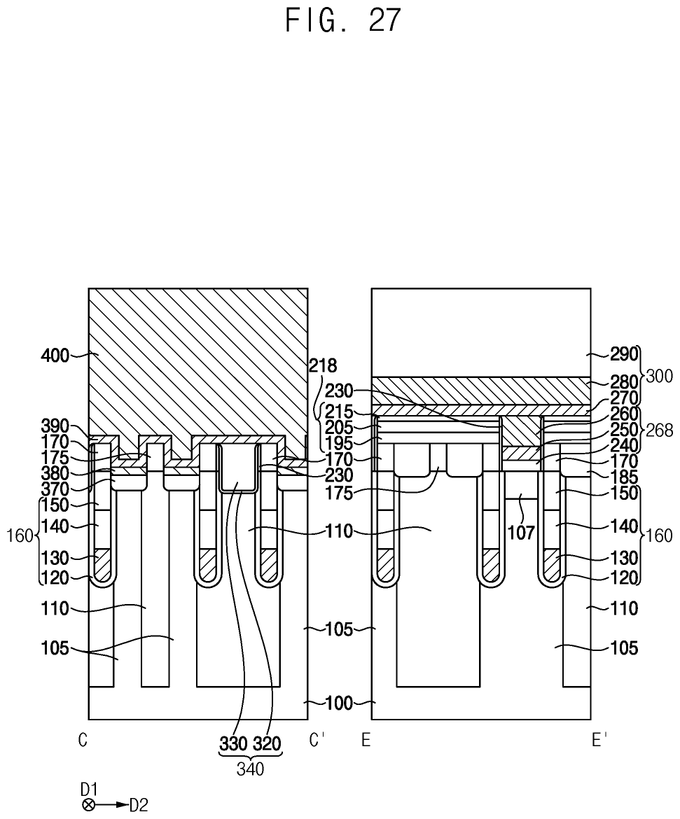

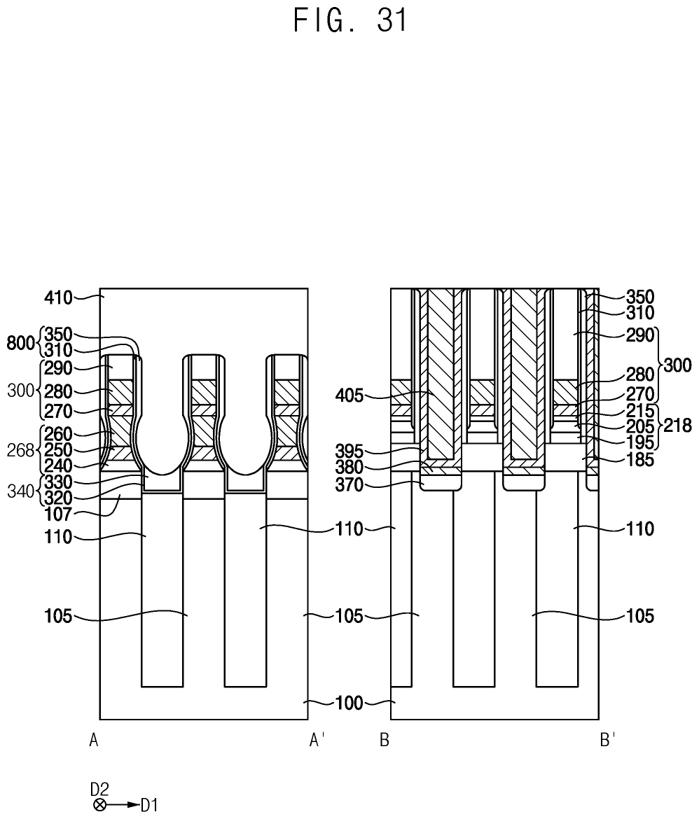

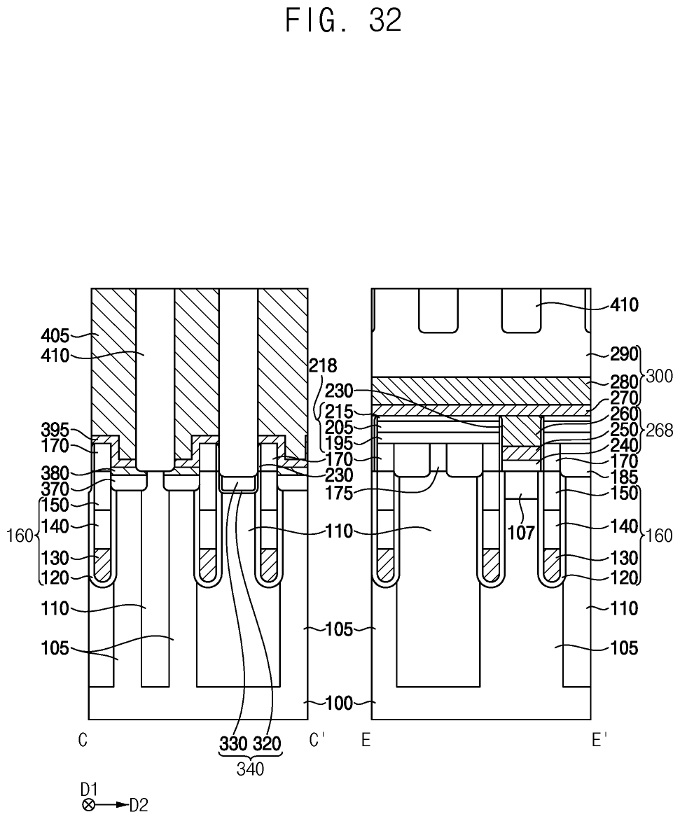

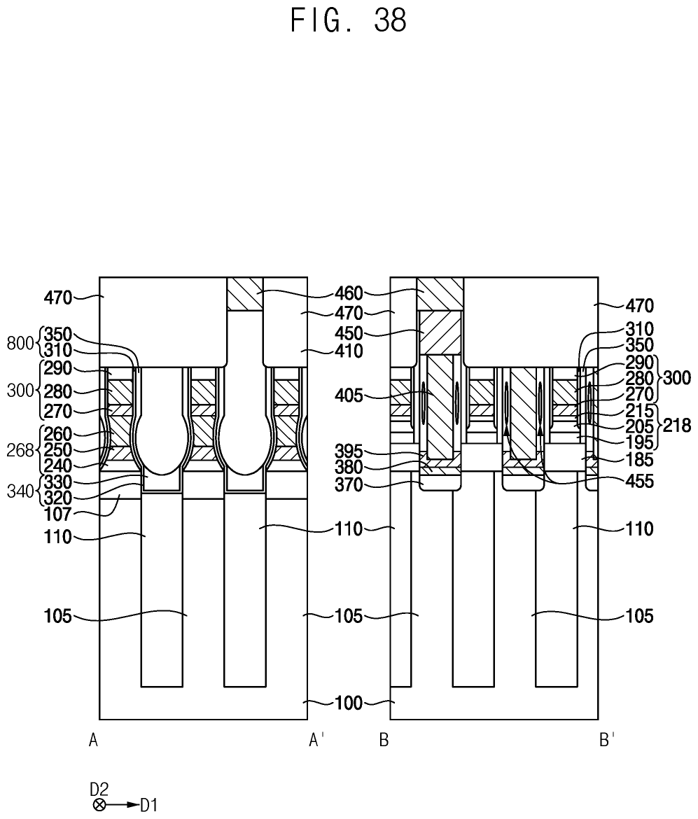

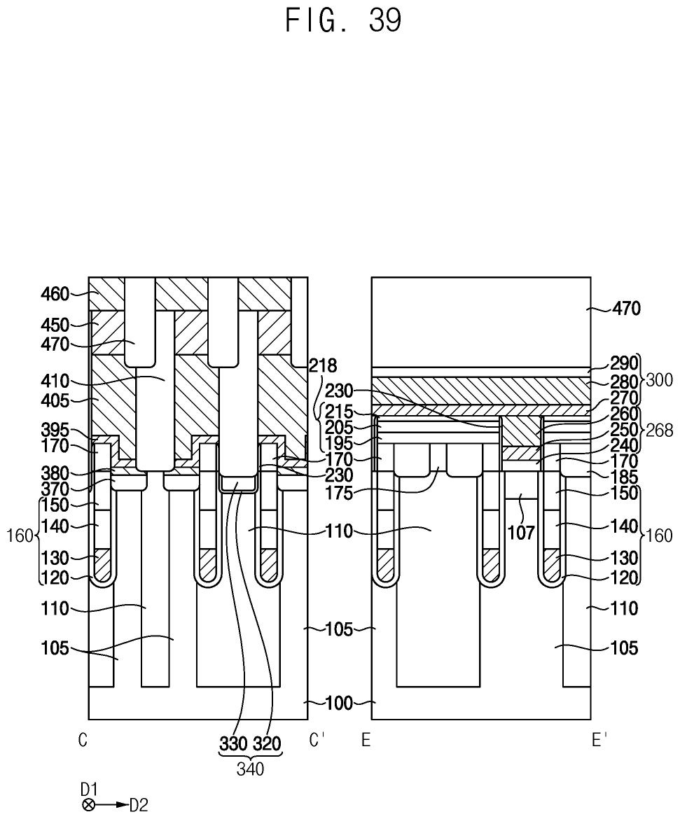

FIGS. 4 to 39 are plan views and cross-sectional views illustrating a method of manufacturing a semiconductor device in accordance with example embodiments. Specifically, FIGS. 4, 7, 10, 13, 16, 19, 22, 25, 30, 35 and 37 are the plan views, each of FIGS. 5, 8, 11, 14, 17, 20, 23, 26, 28, 31, 33, 36 and 38 includes cross-sectional views taken along lines A-A′ and B-B′, respectively, of a corresponding plan view, and each of FIGS. 6, 9, 12, 15, 18, 21, 24, 27, 29, 32, 34 and 39 includes cross-sectional views taken along lines C-C′ and E-E′, respectively, of a corresponding plan view.

Referring to FIGS. 4 to 6, an upper portion of a substrate 100 may be removed to form a recess structure so that an active pattern 105 may be defined, and an isolation pattern 110 may be formed to fill the recess structure.

In an example embodiment, the recess structure may include a first recess extending in the third direction D3 and a second recess extending in the first direction D1 to be connected to the first recess.

In example embodiments, the active pattern 105 may extend in the third direction D3 to a certain length on the substrate 100, and a plurality of active patterns 105 may be spaced apart from each other in the first direction D1 to form an active pattern row. In addition, a plurality of active pattern rows may be spaced apart from each other in the second direction D2 on the substrate 100 to form an active pattern array.

Upper portions of the active pattern 105 and the isolation pattern 110 may be removed to form a third recess, and a gate insulation layer may be formed on an inner wall of the third recess. A first conductive layer may be formed on the gate insulation layer, an upper portion of the first conductive layer may be removed to form a first conductive pattern 130, a second conductive layer may be formed on the first conductive pattern 130 and the gate insulation layer, and an upper portion of the second conductive layer may be removed to form a second conductive pattern 140. A first mask layer may be formed on the second conductive pattern 140 and the gate insulation layer, and the first mask layer and the gate insulation layer may be planarized until an upper surface of the active pattern 105 and an upper surface of the isolation pattern 110 are exposed to form a first mask 150 and a gate insulation pattern 120, respectively.

The gate insulation pattern 120, the first and second conductive patterns 130 and 140 and the first mask 150 in the third recess may collectively form a gate structure 160. In example embodiments, the gate structure 160 may extend in the first direction D1, and a plurality of gate structures 160 may be spaced apart from each other in the second direction D2. In an example embodiment, two gate structures 160 spaced apart from each other in the second direction D2 may be formed at an upper portion of a single active pattern 105 (see, e.g., FIG. 4). Hereinafter, a portion of the active pattern 105 between the two gate structures 160 may be referred to as a central portion thereof, and a portion of the active pattern 105 at an opposite side of the central portion of the active pattern 105 with respect to a corresponding one of the two gate structures 160 (e.g., portions that are not between the two gate structures 160) may be referred to as an end portion thereof.

In another example embodiment, a dummy gate structure extending in the first direction D1 through an upper portion of the isolation pattern 110 between the active pattern rows and the upper portion of each active pattern 105 adjacent to the upper portion of the isolation pattern 110 between the active pattern rows may be further formed.

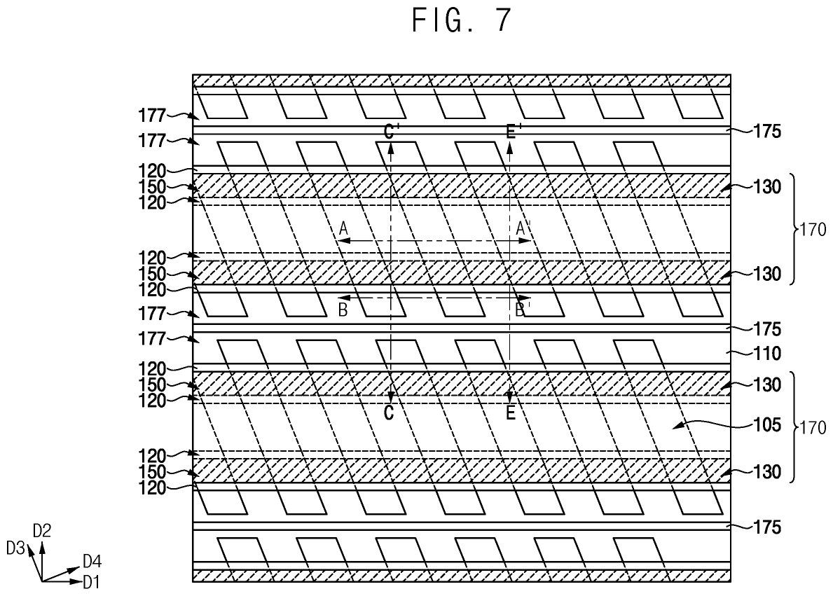

Referring to FIGS. 7 to 9, first and second mold layers 170 and 175 may be formed on the active pattern 105, the isolation pattern 110 and the gate structure 160, and a first opening 177 may be formed between the first and second mold layers 170 and 175.

In example embodiments, each of the first and second mold layers 170 and 175 may extend in the first direction D1, and thus the first opening 177 may also extend in the first direction D1. The first mold layer 170 may cover upper surfaces of the two gate structures 160 extending through the upper portion of the active pattern 105, and the second mold layer 175 may cover an upper surface of a portion of the isolation pattern 110 between the neighboring active pattern rows in the second direction D2.

In an example embodiment, the first mold layer 170 may not cover a portion of the gate insulation pattern 120 of each of the gate structures 160 that is adjacent to the end portion of the active pattern 105, and the second mold layer 175 may be spaced apart from the end portion of the active pattern 105 in the second direction D2.

An etching process using the first and second mold layers 170 and 175 as an etching mask may be performed to partially remove the upper portion of active pattern 105, the upper portion the isolation pattern 110 and an upper portion of gate insulation pattern 120 exposed by the first opening 177, and thus the first opening 177 may be enlarged downwardly. During the etching process, an upper portion of each end portion of the active pattern 105 may be removed.

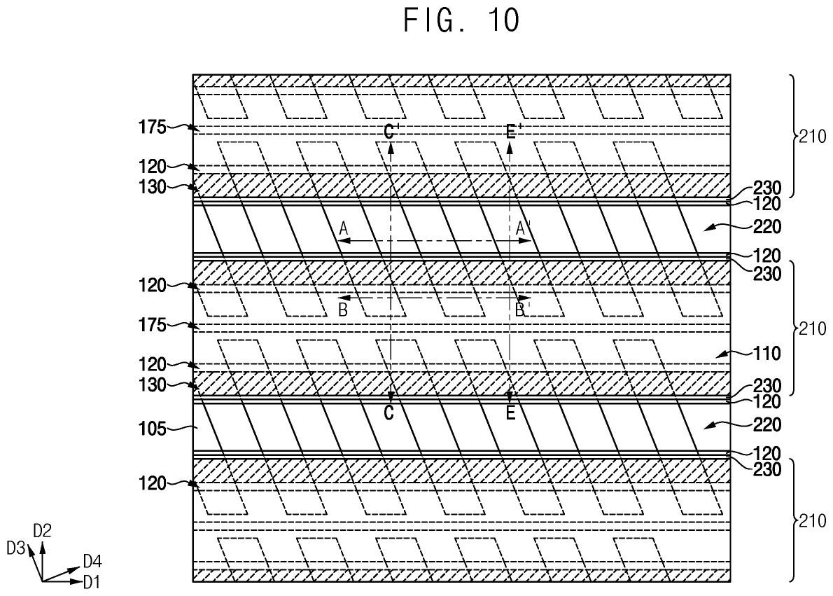

Referring to FIGS. 10 to 12, a third mold layer 180 may be formed on the active pattern 105, the isolation pattern 110, the gate insulation pattern 120 and the first and second mold layers 170 and 175 to fill the first opening 177, and a planarization process may be performed on the third mold layer 180.

In example embodiments, the planarization process may include a chemical mechanical polishing (CMP) process and/or an etch-back process. As the planarization process is performed, the third mold layer 180 may be formed in the first opening 177, and may extend in the first direction D1.

First to third buffer layers 190, 200 and 210 may be sequentially stacked on the first to third mold layers 170, 175 and 180 in a vertical direction substantially perpendicular to the upper surface of the substrate 100, and a second opening 220 may be formed through the first to third buffer layers 190, 200 and 210 and the first mold layer 170 under the first to third buffer layers 190, 200 and 210 to expose the upper surfaces of the active pattern 105 and the isolation pattern 110.

The first buffer layer 190 may be formed of or include an oxide, e.g., silicon oxide, the second buffer layer 200 may be formed of or include, e.g., a high-k material, and the third buffer layer 210 may be formed of or include an insulating nitride, e.g., silicon nitride.

In example embodiments, the second opening 220 may extend in the first direction D1 to expose the central portion of each of the active patterns 105 in the active pattern row, a portion of the isolation pattern 110 adjacent to the central portion of each of the active patterns 105 in the first direction D1, and a portion of the gate insulation pattern 120 neighboring the central portion of each of the active patterns 105 and the gate insulation pattern 120 in the second direction D2.

A first spacer layer may be formed on the first mold layer 170, the active pattern 105, the isolation pattern 110 and the gate insulation pattern 120 exposed by the second opening 220 and the first to third buffer layers 190, 200 and 210, and an anisotropic etching process may be performed on the first spacer layer to form a first spacer 230 on each of sidewalls of the second opening 220 in the second direction D2. The first spacer 230 may be formed of or include, e.g., silicon nitride, silicon oxycarbide (SiOC), silicon oxycarbonitride (SiOCN), etc.

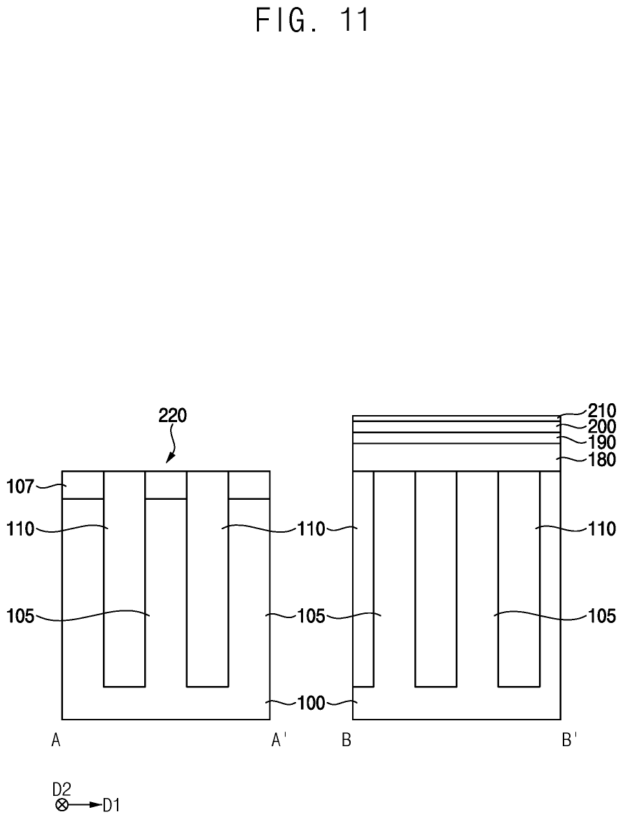

A cleaning process may be additionally performed, and a doping process of implanting impurities, e.g., a gas phase doping (GPD) process may be performed on an upper portion of the central portion of the active pattern 105 exposed by the second opening 220 to form a first impurity region 107 (see, e.g., FIG. 11).

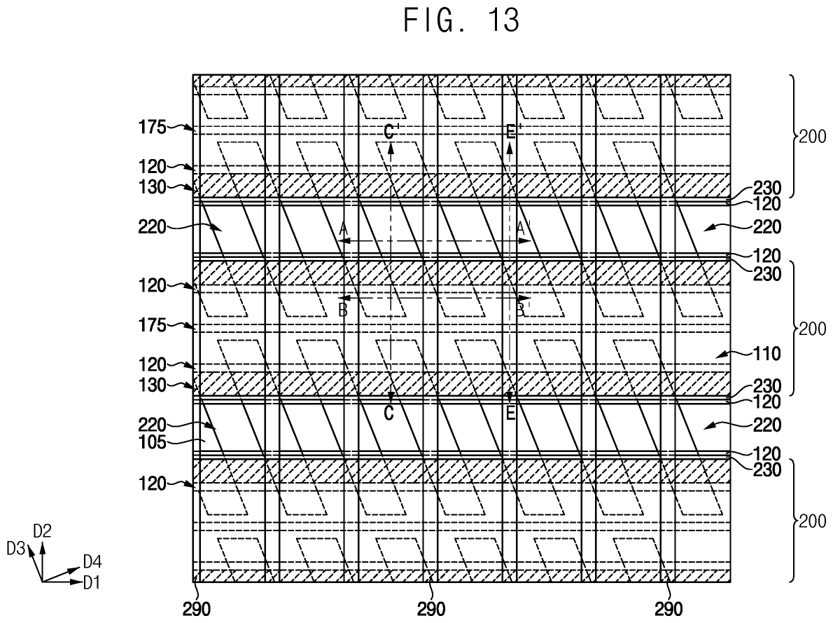

Referring to FIGS. 13 to 15, a pad layer, a first ohmic contact layer and a second metal layer may be sequentially formed in the second opening 220.

The pad layer may be formed of or include, e.g., polysilicon doped with impurities. The first ohmic contact layer may be formed by forming a first metal layer on the pad layer and performing a heat treatment process on the first metal layer so that the first metal layer and the pad layer may be reacted with each other. Thus, the first ohmic contact layer may be formed of or include a metal silicide, e.g., cobalt silicide, nickel silicide, titanium silicide, etc.

In an example embodiment, the second metal layer may be independently formed on the first ohmic contact layer. Alternatively, a lower portion of the first metal layer may be reacted with the first pad layer to form the first ohmic contact layer, and a portion of the first metal layer that is not reacted with the first metal layer may remain as the second metal layer.

A planarization process may be further performed on an upper portion of the second metal layer, and thus an upper surface of the second metal layer may be substantially coplanar with an upper surface of the third buffer layer 210.

A first barrier layer, a third metal layer and a second mask layer may be sequentially stacked on the third buffer layer 210, the second metal layer and the first spacer 230 in the vertical direction, the second mask layer may be patterned to form a second mask 290, and an etching process using the second mask 290 as an etching mask may be performed to pattern the third metal layer, the barrier layer and the third buffer layer 210, and furthermore, the second metal layer, the first ohmic contact layer and the pad layer may also be patterned.

Accordingly, the pad layer, the first ohmic contact layer and the second metal layer may be transformed into a pad 240, a first ohmic contact pattern 250 and a second metal pattern 260, respectively, and the pad 240, the first ohmic contact pattern 250 and the second metal pattern 260 collectively form a first contact structure 268. In example embodiments, a plurality of first contact structures 268 may be spaced apart from each other in the second opening 220 in the first direction D1.

The first barrier layer and the third metal layer may be transformed into a first barrier pattern 270 and a third metal pattern 280, respectively. The first barrier pattern 270, the third metal pattern 280 and the second mask 290 sequentially stacked in the vertical direction may collectively form a bit line structure 300. In example embodiments, the bit line structure 300 may extend in the second direction D2, and a plurality of bit line structures 300 may be spaced apart from each other in the first direction D1.

The bit line structure 300 may overlap the central portions of the active patterns 105 disposed in the second direction D2, and the first contact structure 268 may be interposed between the bit line structure 300 and each of the active patterns 105 to electrically connect the bit line structure 300 and each of the active patterns 105 to each other.

The third buffer layer 210 may be patterned to remain as a third buffer 215 under the bit line structure 300, and the second buffer layer 200 may also be partially removed.

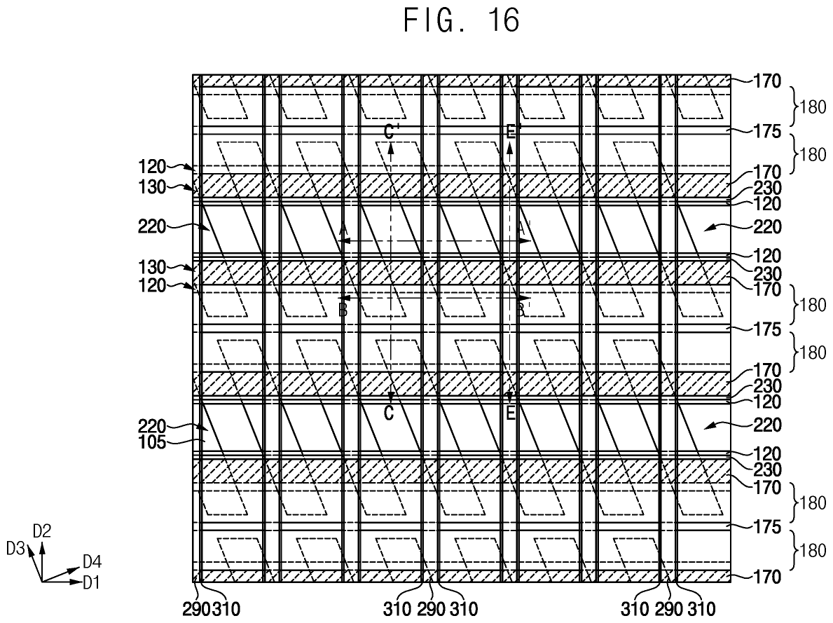

Referring to FIGS. 16 to 18, a second spacer layer may be formed on the bit line structure 300, the first contact structure 268, the third buffer 215, the second buffer layer 200 and the first spacer 230, and on the active pattern 105, the isolation pattern 110 and the gate insulation pattern 120 exposed by the second opening 220, and an anisotropic etching process may be performed on the second spacer layer to form a second spacer 310 on sidewalls of the bit line structure 300, the first contact structure 268 and the third buffer 215.

For example, a wet etching process may be performed on the second buffer layer 200, and thus the second buffer layer 200 may remain as a second buffer 205 under the third buffer 215 and the second spacer 310.

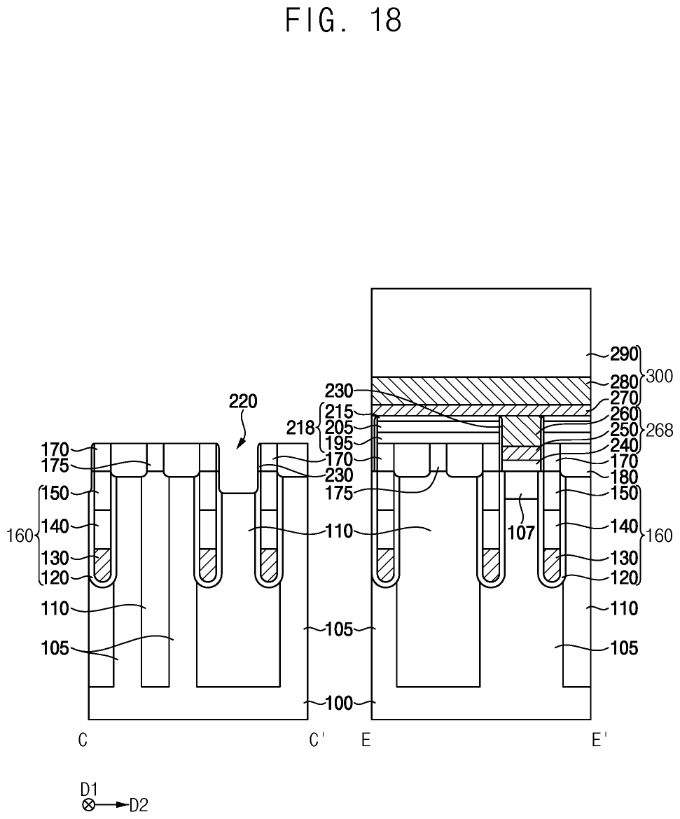

An etching process, for example, a dry etching process or a wet etching process may be performed on the first buffer layer 190 to form a first buffer 195, and the first buffer 195 may remain under the second buffer 205. The first to third buffers 195, 205 and 215 sequentially stacked in the vertical direction may collectively form a buffer structure 218. In example embodiments, a plurality of buffer structures 218 may be spaced apart from each other by the first contact structure 268 and the first spacer 230 in the second direction D2 under the bit line structure 300 (see, e.g., FIG. 18).

As the etching process is performed, upper surfaces of portions of the first to third mold layers 170, 175 and 180, which may not be overlapped with the bit line structure 300 in the vertical direction, may be exposed, and the upper portions of the active pattern 105, the isolation pattern 110 and the gate insulation pattern 120 exposed by the second opening 220 may also be partially removed.

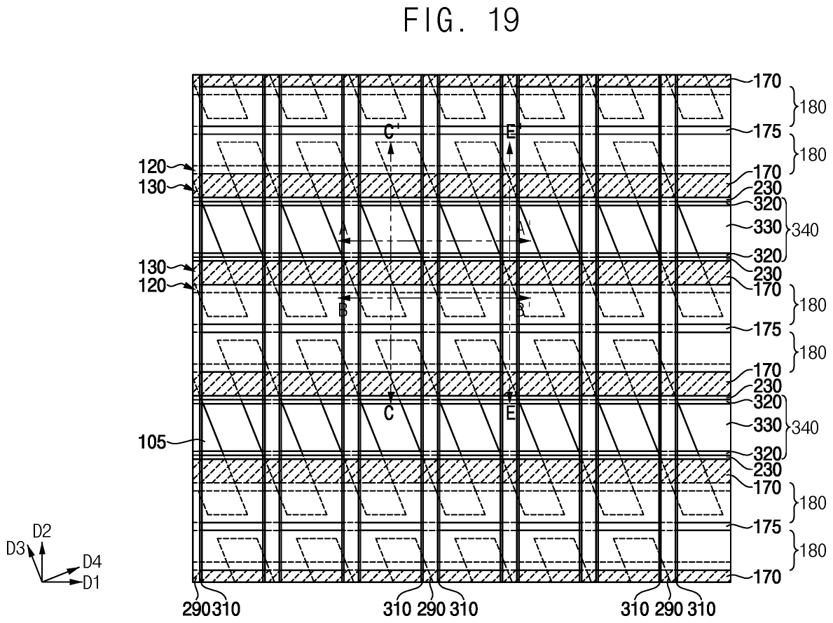

Referring to FIGS. 19 to 21, a filling structure 340 may be formed in the second opening 220.

In example embodiments, the filling structure 340 may be formed by forming a first filling layer on the second spacer 310, the first and second buffers 195 and 205 and the first spacer 230, and on the active pattern 105, the isolation pattern 110 and the gate insulation pattern 120 exposed by the second opening 220, forming a second filling layer on the first filling layer to fill the second opening 220, and performing an etching process on the first and second filling layers.

Thus, a first filling pattern 320 may be formed on upper surfaces and upper sidewalls of the active pattern 105, the isolation pattern 110 and the gate insulation pattern 120 exposed by the second opening 220, a sidewall of the first spacer 230 and a lower sidewall of the second spacer 310, a second filling pattern 330 may be formed to fill a remaining portion of the second opening 220, and the first and second filling patterns 320 and 330 may collectively form the filling structure 340.

In example embodiments, a plurality of filling structures 340 may be spaced apart from each other in the first direction D1 by the first contact structure 268. In example embodiments, an upper surface of the filling structure 340 may be substantially coplanar with the upper surfaces of the first to third mold layers 170, 175 and 180 and an upper surface of the first spacer 230.

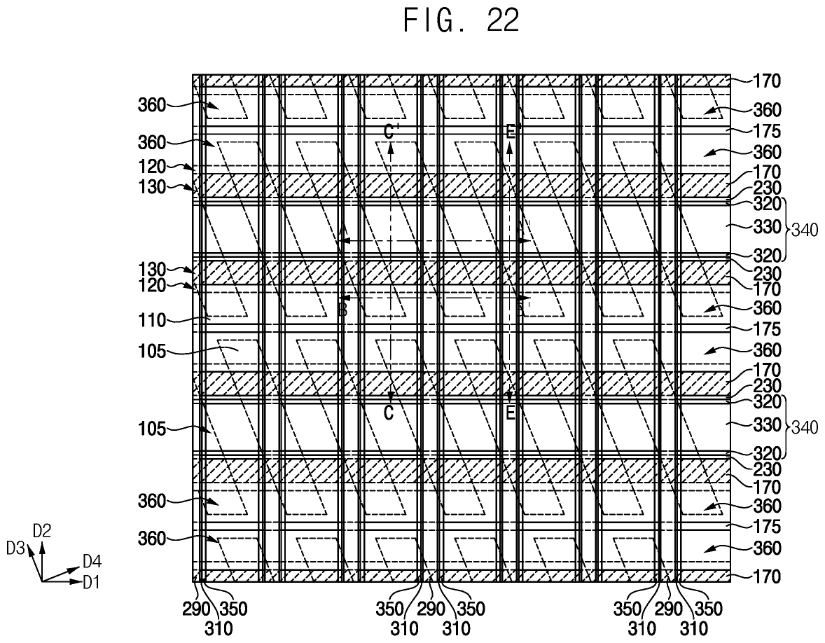

Referring to FIGS. 22 to 24, a third spacer layer may be formed on the bit line structure 300, the second spacer 310, the buffer structure 218, the filling structure 340 and the first to third mold layers 170, 175 and 180, and an anisotropic etching process may be performed on the third spacer layer to form a third spacer 350 on sidewalls of the second spacer 310 and the buffer structure 218.

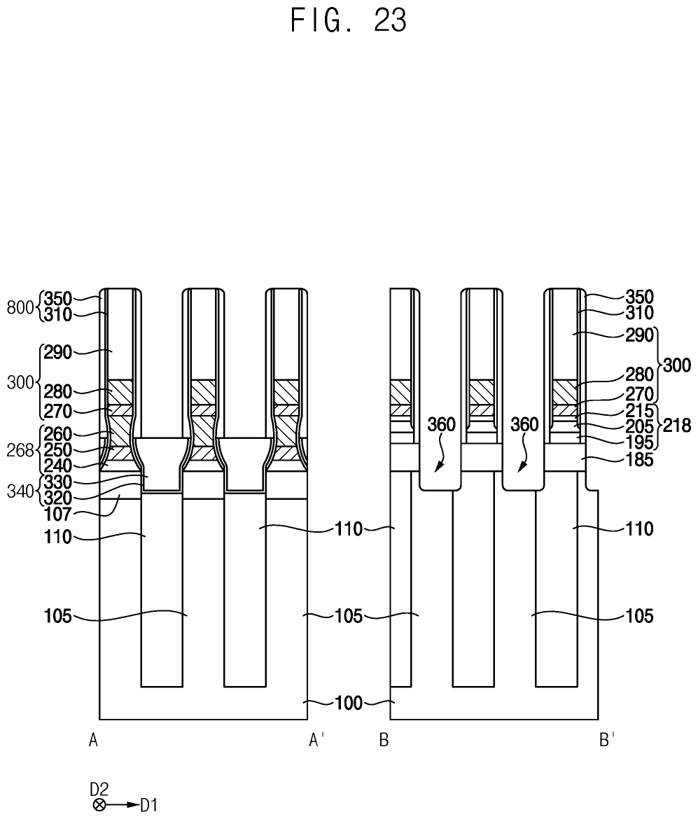

The third spacer 350 may cover an uppermost surface of the first filling pattern 320 in the filling structure 340. The third spacer 350 may be formed of or include an insulating nitride, e.g., silicon nitride. The second and third spacers 310 and 350 on the sidewall in the first direction D1 of the bit line structure 300 may collectively form a spacer structure 800 (see, e.g., FIG. 23).

The third mold layer 180 may be etched by performing an etching process using the bit line structure 300 and the spacer structure 800 as an etching mask, and thus a third opening 360 may be formed to expose the upper surfaces of the active pattern 105, the isolation pattern 110 and the gate insulation pattern 120 under the third mold layer 180.

As the etching process is performed, the third mold layer 180 extending in the first direction D1 may be transformed into a plurality of third molds 185 spaced apart from each other in the first direction D1, and each of the third molds 185 may be formed under the buffer structure 218, the second spacer 310 and the third spacer 350. During the etching process, the upper portions of the active pattern 105, the isolation pattern 110 and the gate insulation pattern 120 exposed by the third opening 360 may also be partially etched.

In example embodiments, the third opening 360 may be formed at each of opposite sides of the second mold layer 175 in the second direction D2 between bit line structures 300 adjacent to each other in the first direction D1.

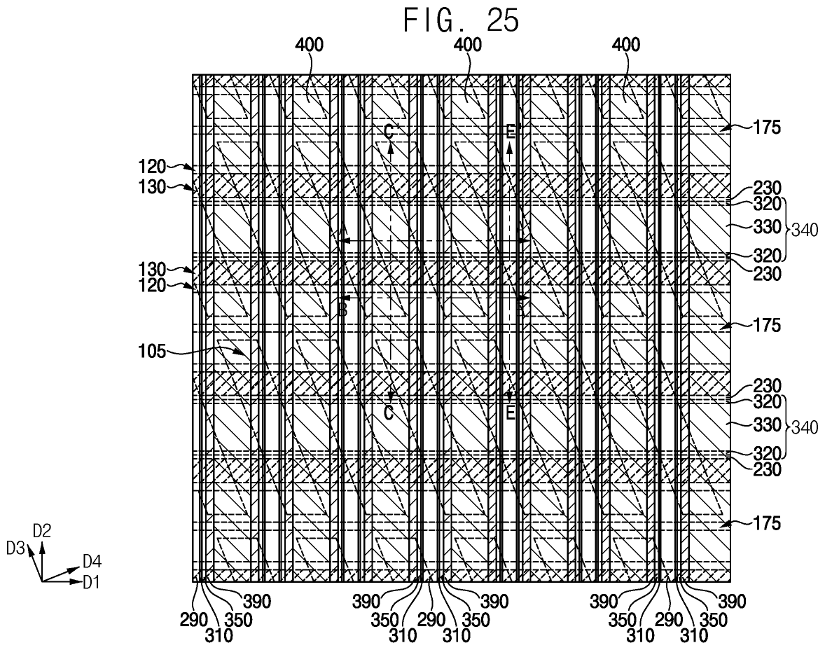

Referring to FIGS. 25 to 27, a second contact structure 370 and a second ohmic contact pattern 380 may be formed in the third opening 360.

In an example embodiment, the second contact structure 370 may be formed by forming a second contact layer through a deposition process on the bit line structure 300, the spacer structure 800, the filling structure 340 and the buffer structure 218, and on the active pattern 105, the isolation pattern 110 and the gate insulation pattern 120 exposed by the third opening 360, and performing, e.g., an etch-back process to remove an upper portion of the second contact layer. Thus, an upper surface of the second contact structure 370 may be lower than lower surfaces of the first and second mold layers 170 and 175 and the third mold 185, however, the inventive concept is not limited thereto. The second contact structure 370 may be formed of or include, e.g., polysilicon doped with impurities.

In another example embodiment, the second contact structure 370 may be formed by a selective epitaxial growth (SEG) process.

In example embodiments, a plurality of second contact structures 370 may be spaced apart from each other in the first and second directions D1 and D2, and a plurality of second ohmic contact patterns 380 may be spaced apart from each other in the first and second directions D1 and D2.

A second barrier layer 390 may be formed on the second ohmic contact pattern 380, the first and second mold layers 170 and 175, the third mold 185, the filling structure 340, the buffer structure 218, the bit line structure 300 and the spacer structure 800, a third contact layer 400 may be formed on the second barrier layer 390, and a planarize process may be performed on the third contact layer 400 and the second barrier layer 390 until the upper surface of the bit line structure 300 is exposed.

In example embodiments, each of the second barrier layer 390 and the third contact layer 400 may extend in the second direction D2. A plurality of second barrier layers 390 may be spaced apart from each other in the first direction D1, and a plurality of third contact layers 400 may be spaced apart from each other in the first direction D1.

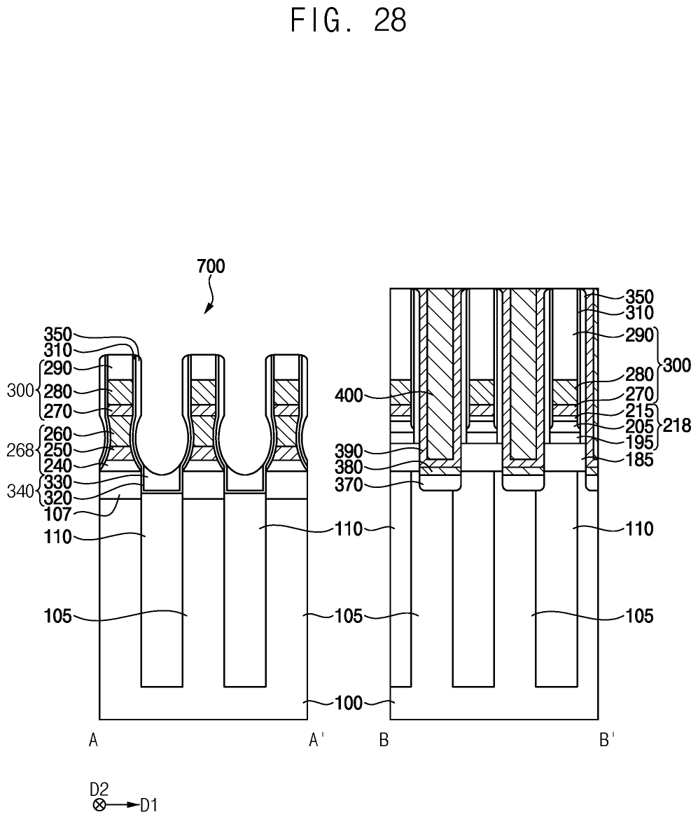

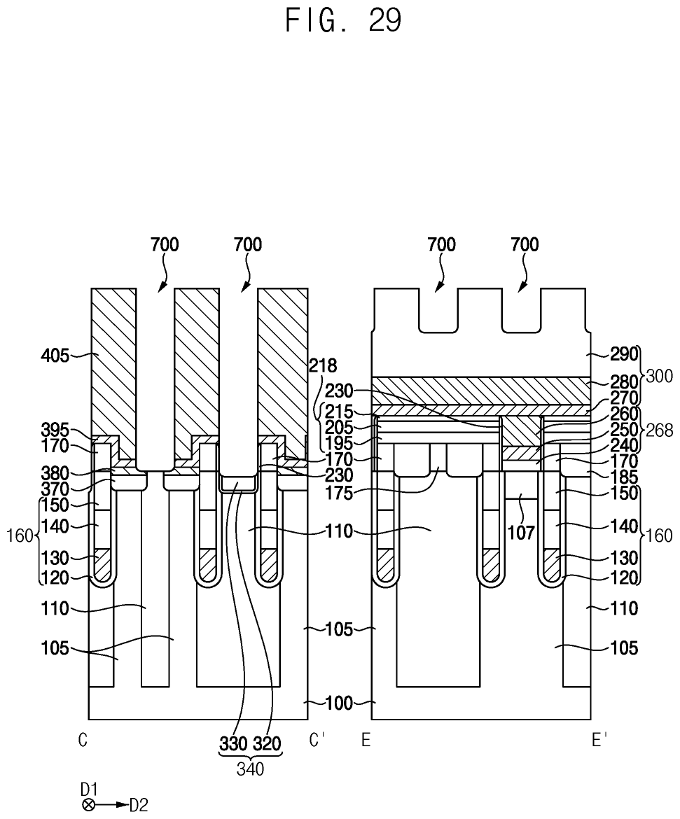

Referring to FIGS. 28 and 29, an etching mask having a fourth opening extending in the first direction D1 may be formed on the bit line structure 300, the spacer structure 800, the second barrier layer 390 and the third contact layer 400, an etching process may be performed using the etching mask to partially etch the second barrier layer 390 and the third contact layer 400 and an upper portion of the filling structure 340 and the second mold layer 175 under the second barrier layer 390 and the second mold layer 175, and thus the second mold layer 175 extending in the first direction D1 may remain only under the bit line structure 300 so as to be divided into a plurality of second mold layers 175 spaced apart from each other in the first direction D1.

During the etching process, an upper lateral portion of the second ohmic contact pattern 380 adjacent to the second mold layer 175 may also be partially removed. Thus, a fifth opening 700 may be formed through the second barrier layer 390 and the third contact layer 400 to expose the upper surface of the isolation pattern 110 and an upper sidewall of the second ohmic contact pattern 380 adjacent to the isolation pattern 110, the upper surface of the filling structure 340 and a sidewall of the first spacer 230.

The second barrier layer 390 extending in the second direction D2 may be divided into a plurality of second barrier patterns 395 spaced apart from each other in the second direction D2, and the third contact layer 400 extending in the second direction D2 may be divided into a plurality of third contact structures 405 spaced apart from each other in the second direction D2.

During the etching process, an upper portion of the second mask 290 of a portion of the bit line structure 300 exposed by the fourth opening may also be etched to be removed, and thus a portion of the spacer structure 800 on an upper surface and an upper sidewall of the portion of the bit line structure 300 may also be removed.

In example embodiments, the fifth opening 700 may extend in the first direction D1 between the third contact structures 405, and a bottom of a portion of the fifth opening 700 on the bit line structure 300 may be higher than bottoms of other portions of the fifth opening 700. For example, the bottom of a first one of the fifth openings 700 may be at a lower level than the bottom of a second one of the fifth openings 700.

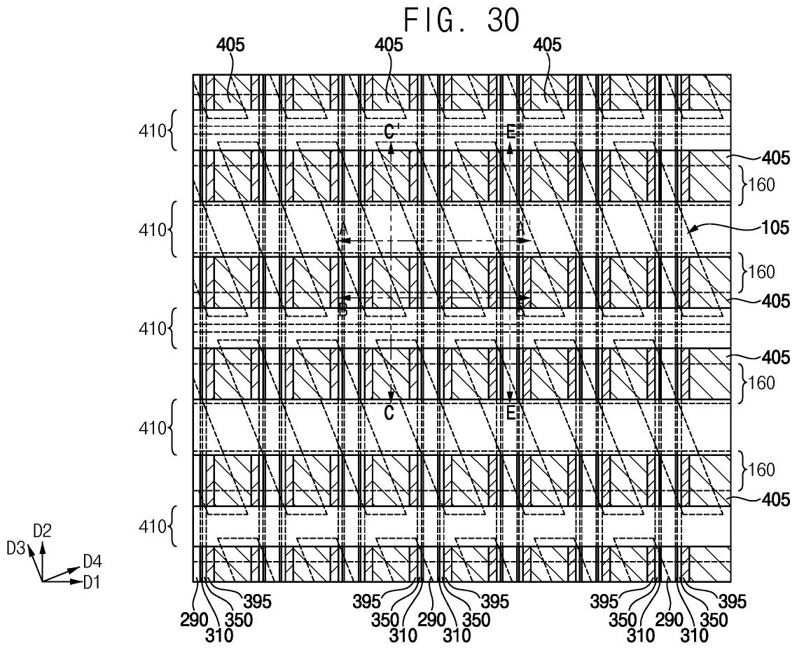

Referring to FIGS. 30 to 32, after removing the etching mask, a fence pattern 410 may be formed to fill the fifth opening 700.

The fence pattern 410 may be formed by forming a fence layer to fill the fifth opening 700, and removing an upper portion of the fence layer until an upper surface of the third contact structure 405 is exposed through, e.g., an etch back process. In example embodiments, the fence pattern 410 may extend in the first direction D1 between the third contact structures 405, and a bottom surface of a portion of the fence pattern 410 on the bit line structure 300 may be higher than bottom surfaces of other portions of the fence pattern 410.

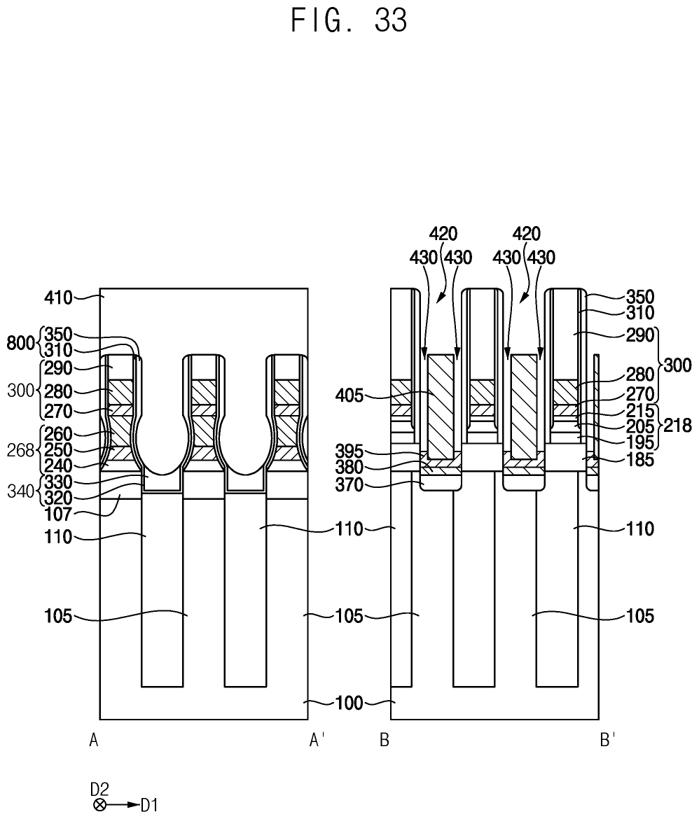

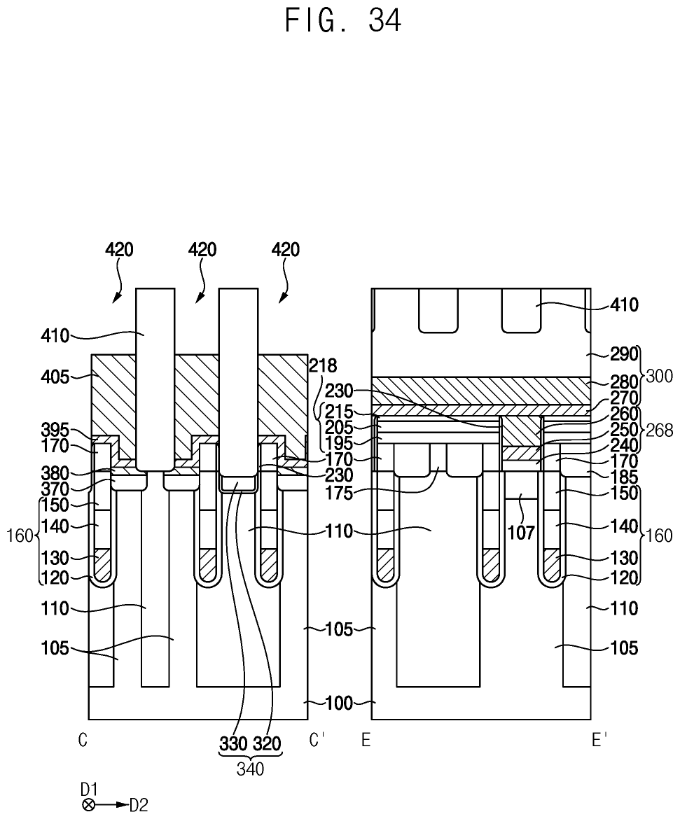

Referring to FIGS. 33 and 34, upper portions of the second barrier pattern 395 and the third contact structure 405 may be removed by, e.g., an etch-back process to form a fourth recess 420, and thus upper surfaces of the second barrier pattern 395 and the third contact structure 405 may be lower than the upper surface of the bit line structure 300.

The second barrier pattern 395 exposed by the fourth recess 420 may be partially removed by, e.g., a wet etching process, and thus a gap 430 exposing sidewalls in the first direction D1 of the third spacer 350 and the third contact structure 405 may be formed.

In an example embodiment, an upper surface of the remaining second barrier pattern 395 may be lower than the upper surfaces of the first and second mold layers 170 and 175 and the third mold 185, however, the inventive concept is not limited thereto.

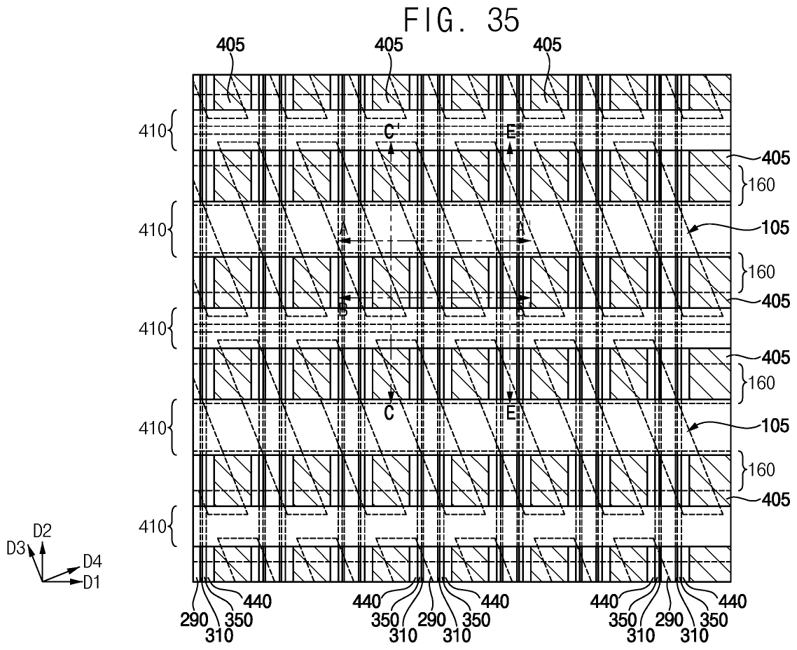

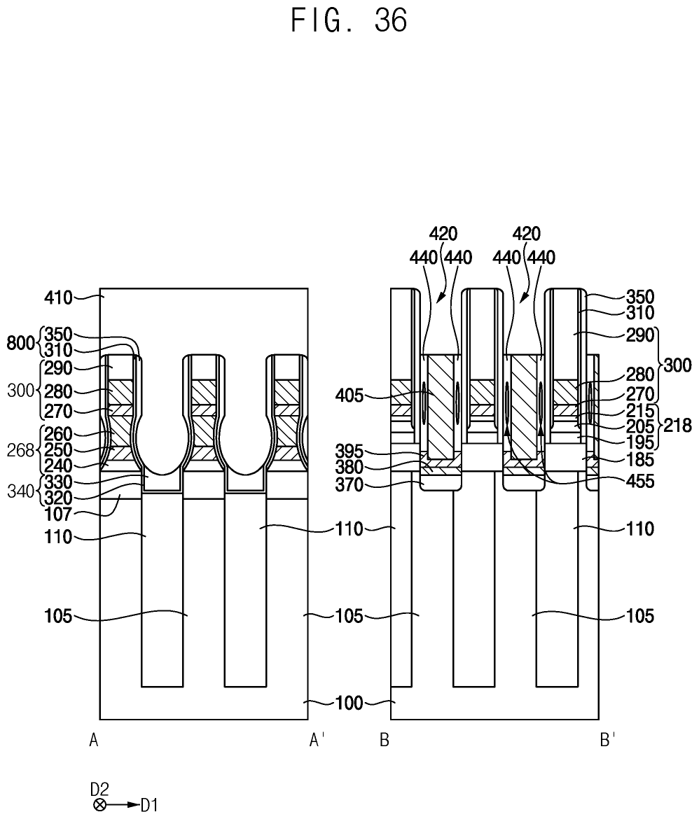

Referring to FIGS. 35 and 36, a third filling pattern 440 may be formed to fill the gap 430.

In an example embodiment, a void 455 may be formed in the third filling pattern 440. The third filling pattern 440 may be formed between the spacer structure 800 on each of opposite sidewalls of the bit line structure 300 in the first direction D1 and the third contact structure 405, and may contact the upper surface of the second barrier pattern 395. In example embodiments, a plurality of third filling patterns 440 may be spaced apart from each other in the first and second directions D1 and D2.

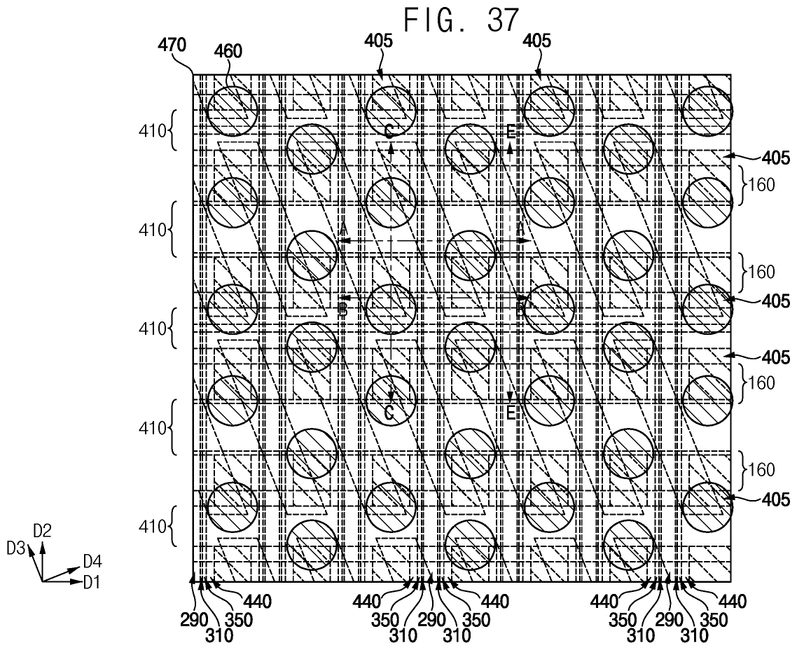

Referring to FIGS. 37 to 39, a fourth contact layer may be formed on the third contact structure 405, the third filling pattern 440, the bit line structure 300, the spacer structure 800 and the fence pattern 410 to fill the fifth opening 700, and a planarization process may be performed on the fourth contact layer until the upper surface of the bit line structure 300 is exposed to form a fourth contact structure 450 in the fifth opening 700.

A landing pad layer may be formed on the fourth contact structure 450, the bit line structure 300, the spacer structure 800 and the fence pattern 410. The landing pad layer and the bit line structure 300, the spacer structure 800, the fence pattern 410 and the fourth contact structure 450 may be partially removed to form a fifth recess, and an insulation pattern 470 may be formed to fill the fifth recess.

Thus, the landing pad layer may be divided into a plurality of landing pads 460 spaced apart from each other in the first and second directions D1 and D2, and each of the landing pads 460 may contact the upper surface of the fourth contact structure 450. In example embodiments, the landing pads 460 may be arranged in a honeycomb pattern in a plan view. Alternatively, the landing pads 460 may be arranged in another pattern, e.g., a grid pattern in a plan view, but the inventive concept is not limited thereto.

Referring back to FIGS. 1 to 3, a first electrode 480 may be formed on the landing pad 460, a dielectric layer 490 may be formed on the first electrode 480 and the insulation pattern 470, and a second electrode 500 may be formed on the dielectric layer 490.

The first electrode 480, the dielectric layer 490 and the second electrode 500 may collectively form a capacitor 510.

The semiconductor device may be manufactured by performing the above processes.

As illustrated above, the first to third mold layers 170, 175 and 180 may be formed on the active pattern 105 and the isolation pattern 110, the first contact structure 268 extending through the first mold layer 170 to contact the central portion of the active pattern 105 may be formed, the bit line structure 300 may be formed on the first contact structure 268, and the filling structure 340 may be formed between the first contact structures 268. The third mold layer 180 between the first and second mold layers 170 and 175 may be patterned using the bit line structure 300 as an etching mask to form the third opening 360 exposing each of end portions of the active pattern 105, and the second contact structure 370 and the second ohmic contact pattern 380 may be formed in the lower portion of the third opening 360.

The second barrier layer 390 and the third contact layer 400 may be formed on the upper surface of the second ohmic contact pattern 380, the fence pattern 410 may be formed through the second barrier layer 390 and the third contact layer 400 so that the second barrier layer 390 and the third contact layer 400 may be divided into the second barrier patterns 395 and the third contact structures 405, respectively, and the upper portions of the second barrier patterns 395 and the third contact structures 405 may be removed to form the fourth recess 420. The second barrier pattern 395 may be partially removed through the fourth recess 420 to form the gap 430, the third filling pattern 440 may be formed in the gap 430, and the fourth contact structure 450, the landing pad 460 and the capacitor 510 may be formed on the third contact structure 405 and the third filling pattern 440.

Thus, the third filling pattern 440 may be formed between the third contact structure 405, which may be electrically connected to the second contact structure 370 on each of end portions of the active pattern 105, and the bit line structure 300, which may overlap the central portion of the active pattern 105 and extend in the second direction D2, so that the electrical short between the third contact structure 405 and the bit line structure 300 may be prevented or reduced. Additionally, the void 455 may be formed in the third filling pattern 440, and thus a parasitic capacitance between the bit line structure 300 and the third contact structure 405 may be reduced.

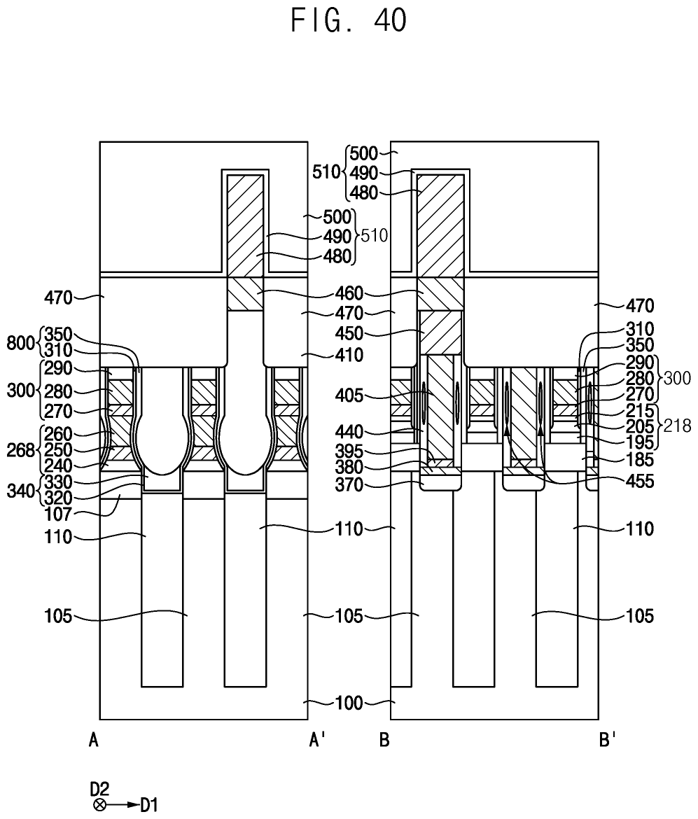

FIG. 40 is a cross-sectional view illustrating a semiconductor device in accordance with example embodiments, which corresponds to FIG. 2.

This semiconductor device may be substantially the same as or similar to the semiconductor device of FIGS. 1 to 3, except for the shape of the second barrier pattern, and thus repeated explanations are omitted herein.

Referring to FIG. 40, the second barrier pattern 395 may cover a lower surface of the third contact structure 405, however, may not cover a lower portion of a sidewall in the first direction D1 of the third contact structure 405.

That is, the second barrier pattern 395 may cover the lower surface of the third contact structure 405, however, the lower portion of the sidewall in the first direction D1 of the third contact structure 405 may be covered by the third filling pattern 440 instead of the second barrier pattern 395. In example embodiments, the second barrier pattern 395 may contact a lower portion of a sidewall in the first direction D1 of the third filling pattern 440. Additionally, a lowermost surface of the second barrier pattern 395 may be substantially coplanar with a lowermost surface of the third filling pattern 440.

When the second barrier pattern 395 exposed by the fourth recess 420 is partially removed by, e.g., a wet etching process through the processes illustrated with reference to FIGS. 33 and 34, as the gap 430 exposes an upper surface of the second ohmic contact pattern 380 under the second barrier pattern 395, the second barrier pattern 395 may cover the lower surface of the third contact structure 405 but may not cover the lower portion of the sidewall in the first direction D1 of the third contact structure 405.

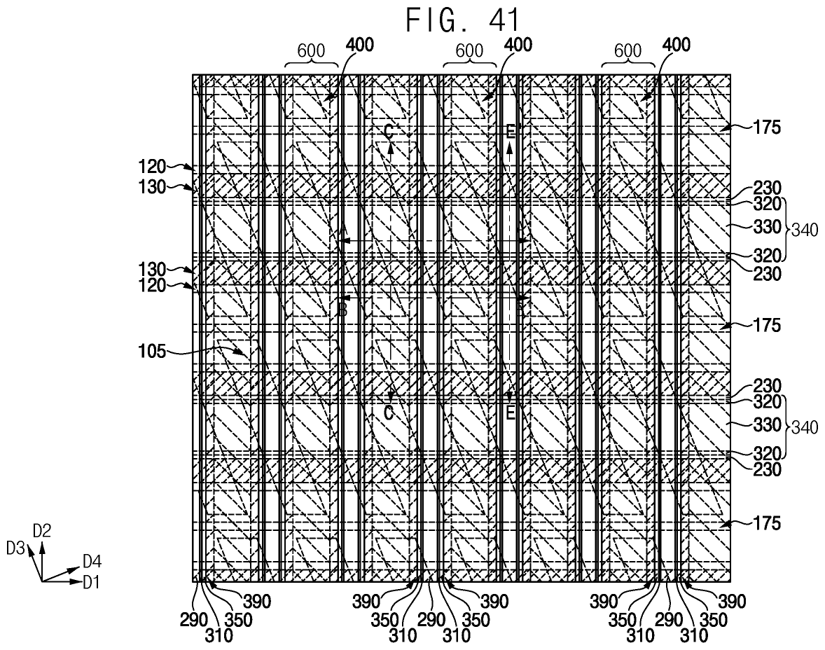

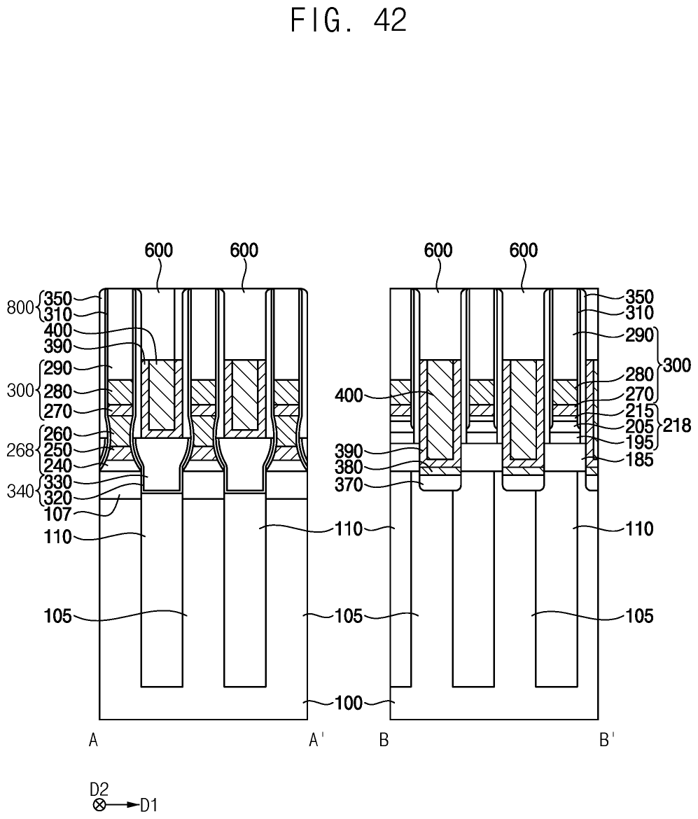

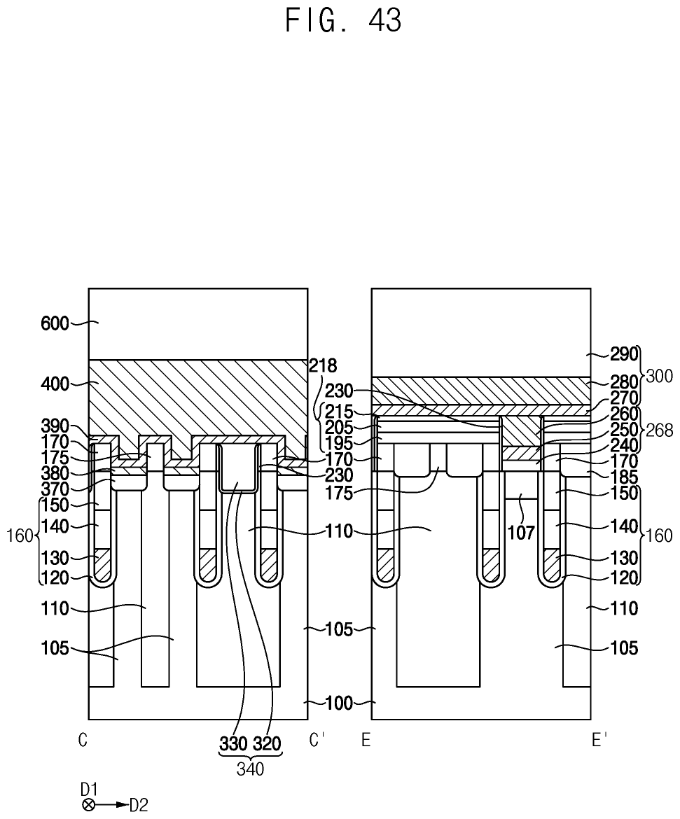

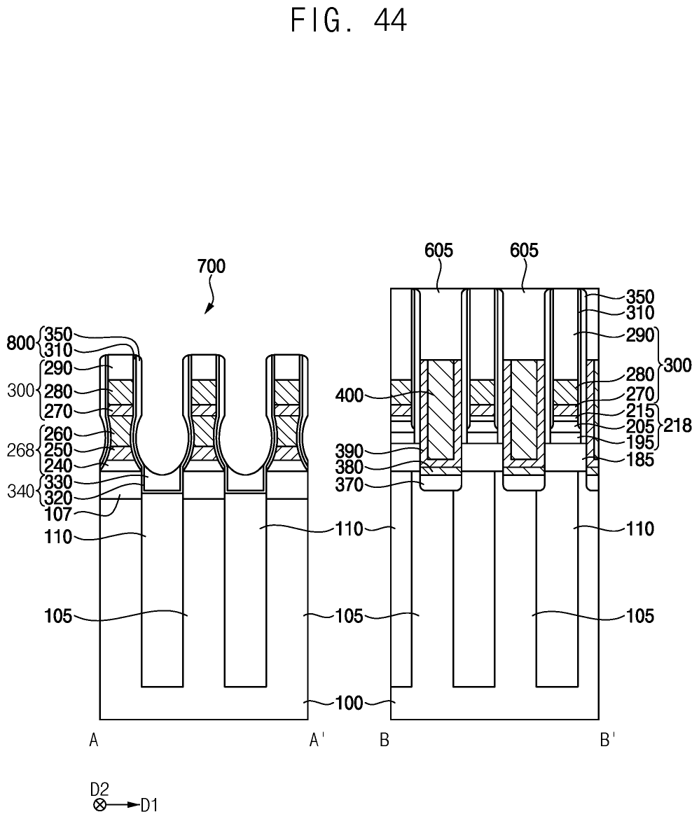

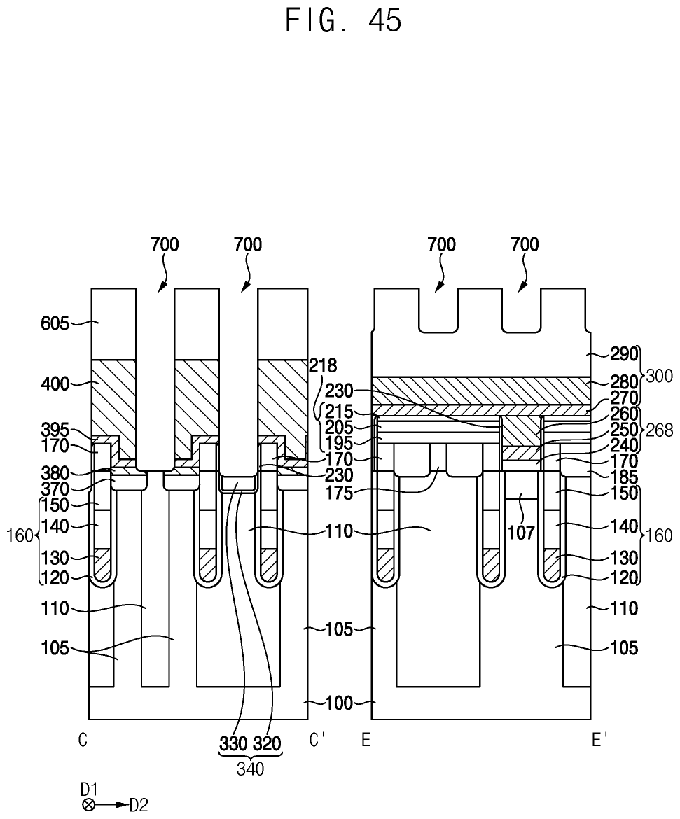

FIGS. 41 to 45 are a plan view and cross-sectional views illustrating a method of manufacturing a semiconductor device in accordance with example embodiments. Particularly, FIG. 41 is the plan view, each of FIGS. 42 and 44 includes cross-sections taken along lines A-A′ and B-B′ of corresponding plan views, respectively, and each of FIGS. 43 and 45 includes cross-sections taken along lines C-C′ and E-E′ of corresponding plan views, respectively.

This method may include processes substantially the same as or similar to those illustrated with reference to FIGS. 4 to 39 and FIGS. 1 to 3, and thus repeated explanations thereof are omitted herein.

Initially, processes substantially the same as or similar to those illustrated with reference to FIGS. 4 to 27 may be performed.

Referring to FIGS. 41 to 43, upper portions of the second barrier layer 390 and the third contact layer 400 may be removed by, e.g., an etch-back process to form a sixth recess extending in the second direction D2, and thus the upper surfaces of the second barrier layer 390 and the third contact layer 400 may be lower than the upper surface of the bit line structure 300.

A sacrificial insulating interlayer 600 may be formed on the second barrier layer 390, the third contact layer 400, the bit line structure 300 and the spacer structure 800 to fill the sixth recess, and a planarization process may be performed on the sacrificial insulating interlayer 600 until the upper surface of the bit line structure 300 is exposed.

Thus, the sacrificial insulating interlayer 600 may extend in the second direction D2, and a plurality of sacrificial insulating interlayers 600 may be spaced apart from each other in the first direction D1. The sacrificial insulating interlayer 600 may be formed of or include, e.g., amorphous carbon layer (ACL), spin-on-hardmask (SOH), etc.

Referring to FIGS. 44 and 45, processes substantially the same as or similar to those illustrated with reference to FIGS. 28 and 29 may be performed.

Particularly, the etching mask having the fourth opening extending in the first direction D1 may be formed on the bit line structure 300, the spacer structure 800 and the sacrificial insulating interlayer 600, and the sacrificial insulating interlayer 600, and the third contact layer 400, the second barrier layer 390, an upper portion of the filling structure 340 and the second mold layer 175 under the sacrificial insulating interlayer 600 may be partially etched by an etching process using the etching mask, so that the second mold layer 175 extending in the first direction D1 may be divided into a plurality of pieces spaced apart from each other in the first direction D1, which may remain under the bit line structure 300.

During the etching process, an upper lateral portion of the second ohmic contact pattern 380 adjacent to the second mold layer 175 may be partially removed. Thus, the fifth opening 700 may extend through the second barrier layer 390 and the third contact layer 400 to expose the upper surface of the isolation pattern 110, the upper sidewall of the second ohmic contact pattern 380 adjacent to the isolation pattern 110, the upper surface of the filling structure 340 and the sidewall of the first spacer 230.

The second barrier layer 390, the third contact layer 400 and the sacrificial insulating interlayer 600 extending in the second direction D2 may be divided into the second barrier patterns 395, the third contact structures 405 and sacrificial insulating interlayer patterns 605, respectively.

During the etching process, an upper portion of the second mask 290 of a portion of the bit line structure 300 exposed by the fourth opening may also be removed, and thus a portion of the spacer structure 800 on an upper surface and an upper sidewall of the portion of the bit line structure 300 may also be removed.

In example embodiments, the fifth opening 700 may extend in the first direction D1 between the sacrificial insulating interlayer patterns 605 and the third contact structures 405, and the bottom of the portion of the fifth opening 700 on the bit line structure 300 may be higher than bottoms of other portions of the fifth opening 700.

The sacrificial insulating interlayer pattern 605 may be removed by, e.g., an ashing process and/or a stripping process, and thus the fourth recess 420 exposing the upper surfaces of the third contact structure 405 and the second barrier pattern 395 may be formed.

Processes substantially the same as or similar to those illustrated with reference to FIGS. 33 and 34 may be performed to partially remove the second barrier pattern 395 exposed by the fourth recess 420, so that the gap 430 exposing the sidewalls in the first direction D1 of the third spacer 350 and the third contact structure 405 may be formed.

Processes substantially the same as or similar to those illustrated with reference to FIGS. 36 to 39 and FIGS. 1 to 3 may be performed to complete the fabrication of the semiconductor device.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor device comprising:
an active pattern array including active patterns on a substrate;
a first contact on a central portion of each of the active patterns;
a bit line on the first contact;
a second contact on an end portion of each of the active patterns;
a third contact on the second contact;
a filling pattern between the bit line and the third contact, the filling pattern including a void therein; and
a capacitor electrically connected to the third contact, wherein
the active pattern array includes active pattern rows spaced apart from each other in a first direction parallel to an upper surface of the substrate,
each of the active pattern rows includes a plurality of active patterns spaced apart from each other in a second direction parallel to the upper surface of the substrate and orthogonal to the first direction,
each of the active patterns extends in a third direction forming an acute angle with the first direction and the second direction, and
the plurality of active patterns in each row of the active pattern rows are aligned with each other in the second direction.

2. The semiconductor device according to claim 1, wherein the bit line extends in the first direction, and
wherein the filling pattern is between a sidewall of the bit line that extends in the first direction and a sidewall of the third contact that extends in the first direction.

3. The semiconductor device according to claim 2, further comprising a spacer between the sidewall the bit line and the filling pattern, the spacer including a nitride.

4. The semiconductor device according to claim 2, further comprising a fence pattern extending in the second direction on the substrate, the fence pattern separating the third contacts from each other.

5. The semiconductor device according to claim 1, wherein the filling pattern includes an oxide.

6. The semiconductor device according to claim 1, wherein the third contact includes a metal, and
wherein the semiconductor device further comprises a barrier pattern covering a lower surface of the third contact and including a metal nitride.

7. The semiconductor device according to claim 6, wherein the barrier pattern contacts a lower surface of the filling pattern.

8. The semiconductor device according to claim 6, wherein the barrier pattern contacts a lower sidewall of the filling pattern.

9. The semiconductor device according to claim 6, further comprising an ohmic contact pattern between the second contact and the barrier pattern, the ohmic contact pattern including a metal silicide.

10. The semiconductor device according to claim 1, further comprising a fourth contact contacting an upper surface of the third contact and an upper surface of the filling pattern, the fourth contact including a metal.

11. A semiconductor device comprising:
an active pattern on a substrate;
a first contact on a central portion of the active pattern;
a bit line on the first contact;
a second contact on an end portion of the active pattern;
a third contact on the second contact;
a filling pattern between the bit line and the third contact, the filling pattern including a void therein;
a barrier pattern on the second contact, the barrier pattern covering a lower surface of the third contact and a lower surface of the filling pattern;
a fourth contact contacting an upper surface of the third contact and an upper surface of the filling pattern; and
a capacitor electrically connected to the fourth contact.

12. The semiconductor device according to claim 11, wherein an uppermost surface of the barrier pattern is higher than a lowermost surface of the third contact.

13. The semiconductor device according to claim 11, wherein an uppermost surface of the barrier pattern is coplanar with a lowermost surface of the filling pattern.

14. The semiconductor device according to claim 11, wherein the bit line extends in a first direction, and
wherein the filling pattern is between a sidewall of the bit line that extends in the first direction and a sidewall of the third contact that extends in the first direction.

15. The semiconductor device according to claim 2, further comprising a spacer between the sidewall of the bit line and the filling pattern, the spacer including a nitride.

16. The semiconductor device according to claim 14, further comprising a fence pattern extending in a second direction on the substrate, the fence pattern separating the third contacts from each other, the second direction being orthogonal to the first direction.

17. A semiconductor device comprising:
an active pattern array including active patterns on a substrate;
an isolation pattern on the substrate, the isolation pattern covering sidewalls of the active patterns;
gates spaced apart from each other in a first direction parallel to an upper surface of the substrate, each of the gates extending through the active patterns and an upper portion of the isolation pattern in a second direction parallel to the upper surface of the substrate and orthogonal to the first direction;
a first contact on a central portion of each of the active patterns;
bit lines spaced apart from each other in the second direction, each of the bit lines extending in the first direction on central portions of the active patterns and the isolation pattern;
a second contact on an end portion of each of the active patterns;
a barrier pattern on the second contact;
a third contact on the barrier pattern;
a filling pattern between the bit line and the third contact, the filling pattern including a void therein;
a fourth contact on the third contact and the filling pattern;
a landing pad on the fourth contact; and
a capacitor on the landing pad, wherein
the active pattern array includes active pattern rows spaced apart from each other in the first direction,
each of the active pattern rows includes a plurality of active patterns spaced apart from each other in the second direction,
each of the active patterns extends in a third direction forming an acute angle with the first direction and the second direction, and
the plurality of active patterns in each row of the active pattern rows are aligned with each other in the second direction.

18. The semiconductor device according to claim 17, further comprising a spacer between each of the bit line and a respective filling pattern, the spacer including a nitride.

19. The semiconductor device according to claim 17, further comprising a fence pattern extending in the second direction on the substrate, the fence pattern separating the third contacts from each other.

20. The semiconductor device according to claim 17, wherein the barrier pattern contacts a lower surface of the filling pattern.
